(19) United States
(12) Patent Application Publication
(10) Pub. No.: US 2025/0384919 A1
(43) Pub. Date: Dec. 18, 2025

(54) SEMICONDUCTOR DEVICE

(71) Applicant: Taiwan Semiconductor Manufacturing Company, Ltd., Hsinchu (TW)

(72) Inventor: Jhon-Jhy LIAW, Zhudong Township (TW)

(21) Appl. No.: 18/741,248

(22) Filed: Jun. 12, 2024

(51) Int. Cl. G11C 11/412; G11C 11/419; H10B 10/00

(52) U.S. Cl. CPC G11C 11/412; G11C 11/419; H10B 10/12

(57) ABSTRACT

A semiconductor device includes a first static random access memory (SRAM) cell, a second SRAM cell, and a first and a second gate end dielectric structures. The first SRAM cell includes a first write port including a first write-port pass-gate (WPG) transistor, a second WPG transistor, a first write-port pull-down (WPD) transistor, and a second WPD transistor, and a first read port including a first read-port pull-down (RPD) transistor and a first read-port pass-gate (RPG) transistor. The second SRAM cell includes a second write port including a third WPG transistor, a fourth WPG transistor, a third WPD transistor, and a fourth WPD transistor, and a second read port including a second RPD transistor and a second RPG transistor. The first gate end dielectric structure is between the first write-port and the first read-port. The second gate end dielectric structure is between the second write-port and the second read-port.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, fin field-effect transistors (FinFETs) and gate-all-around (GAA) transistors have been incorporated into semiconductor devices (including, for example, static random-access memory, or SRAM, cells) to reduce chip footprint while maintaining reasonable processing margins.

However, as semiconductor devices continue to be scaled down, interconnection routing for semiconductor devices uses too many routing resources and therefore impacts the cell scaling as well as memory performance. Accordingly, although existing technologies for fabricating semiconductor devices have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIG. 2 illustrates a circuit diagram for a SRAM cell that can be implemented in an array of two-port SRAM cells in the memory region of FIG. 1, in accordance with some alternative embodiments of the present disclosure.

FIG. 3 is a perspective view of a GAA transistor in the SRAM cell, in accordance with some embodiments of the present disclosure.

FIG. 4 shows a cross-sectional view of a semiconductor device for illustrating an interconnection structure, in accordance with some embodiments of the present disclosure.

FIGS. 5A, 5B, 5C, and 5D illustrate top views (or layouts) of two adjacent SRAM cells in a portion of a array that can be one embodiment of the SRAM cells implemented in the memory region, in accordance with some embodiments of the present disclosure.

FIG. 5E is an X-Z cross-sectional view of the array along a line A-A’ in FIG. 5A, in accordance with some embodiments of the present disclosure.

FIG. 5F is an X-Z cross-sectional view of the array along a line B-B’ in FIG. 5A, in accordance with some embodiments of the present disclosure.

FIG. 5G is a Y-Z cross-sectional view of the array along a line C-C’ in FIG. 5A, in accordance with some embodiments of the present disclosure.

FIG. 5H is a Y-Z cross-sectional view of the array along a line D-D’ in FIG. 5A, in accordance with some embodiments of the present disclosure.

FIG. 5I is a Y-Z cross-sectional view of the array along a line E-E’ in FIG. 5A, in accordance with some embodiments of the present disclosure.

FIGS. 6A, 6B, 6C, 6D, 6E, and 6F illustrate top views (or layouts) of two adjacent SRAM cells in a portion of a array that can be one embodiment of the SRAM cells implemented in the memory region, in accordance with some alternative embodiments of the present disclosure.

FIG. 6G is an X-Z cross-sectional view of the array along a line F-F’ in FIG. 6A, in accordance with some alternative embodiments of the present disclosure.

FIG. 6H is an X-Z cross-sectional view of the array along a line G-G’ in FIG. 6A, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to static random-access memory (SRAM) cells having field-effect transistors (FETs), such as three-dimensional gate-all-around (GAA) transistors, in an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure also relates to layouts and structures thereof of semiconductor devices. More particularly, the present disclosure relates to two-port SRAM cell layout designs and structures. The present disclosure provides a compact two-port SRAM cell design having a width of four gate pitches (the so-called four-gate-pitch SRAM cell) and with multiple metal layers with metal conductors (or tracks) used for connections and over transistors. Transistors such as gate-all-around (GAA) transistors forming the two-port SRAM cell are fabricated over a substrate. Some of the metal conductors such as read bit-line conductors and VDD lines are fabricated in the lowest metal layer without extra landing pad, thereby reducing the capacitance. Other metal conductors such as write word-line conductors, write bit-line conductors, and write bit-line-bar (also referred to as complementary bit-line) conductors are fabricated in higher metal layers. The write word-line conductors, write bit-line conductors, and write bit-line-bar conductors can be made wider than those metal conductors, thereby reducing the resistance.

Embodiments of the present disclosure offer advantages over the existing art, though it should be understood that other embodiments may offer different advantages, not all advantages are necessarily discussed herein, and no particular advantage is required for all embodiments. For example, embodiments discussed herein include an array of two-port SRAM cells each constructed by eight GAA transistors, in which two two-port SRAM cells in adjacent two rows share a read bit-line in the lowest metal layer, that can improve cell performance and reduce the routing complexity of the two-port SRAM cell. Furthermore, write ports and read ports of the two-port SRAM cells are separated by continuous gate end dielectric structures, such that source/drain feature bridge concern is prevented. The details of the present disclosure are described below in conjunction with the accompanying drawings, which illustrate the layout and structure of circuit cells, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

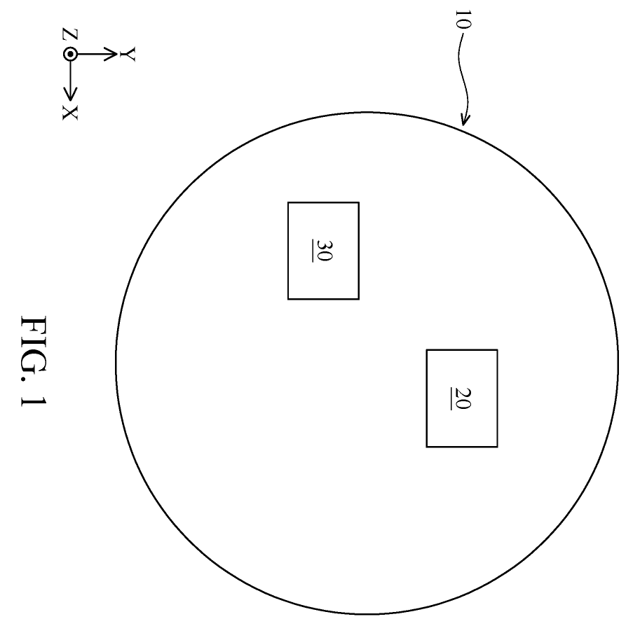

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, p-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or combinations thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of memory cells, each of which includes transistors and interconnection structures (also referred to as routing structures) that combine to provide a storage device and/or a storage function, such as a flip flop, a latch, other suitable semiconductor devices, or combinations thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or combinations thereof.

The logic region 30 can include an array of circuit cells having various logic cells or standard (STD) cells. The logic cells or STD cells may include transistors and interconnection structures that combine to provide a logic device and/or a logic function, such as an inverter, an AND, an NAND, an OR, an NOR, a NOT, an XOR, an XNOR, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of the IC chip 10.

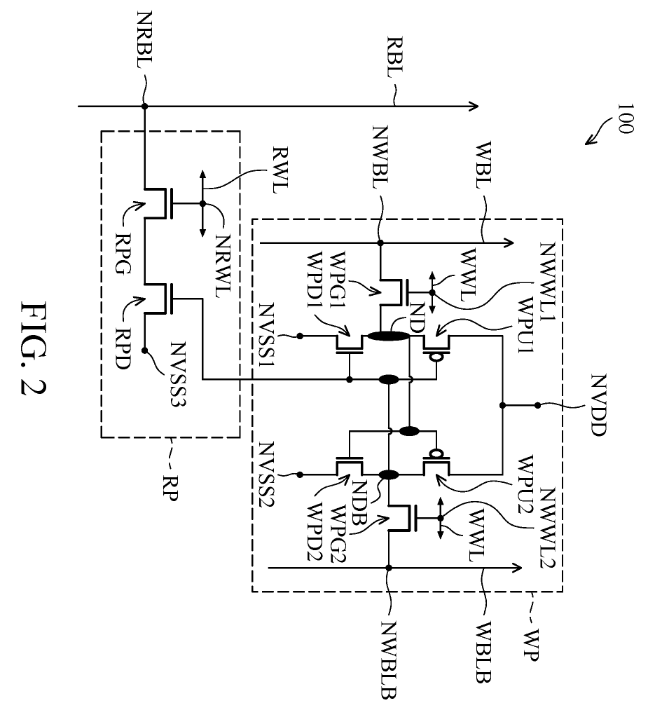

FIG. 2 is a circuit diagram for an SRAM cell 100 that can be implemented in an array of two-port SRAM cells in the memory region 20 of FIG. 1, in accordance with some alternative embodiments of the present disclosure. The SRAM cell 100 includes a write-port circuit WP having data nodes ND and NDB, a read-port circuit RP coupled with data node ND. The SRAM cell 100 may also be referred to as two-port SRAM cells due to the SRAM cell 100 has two-port of write-port circuit and the read-port circuit, as shown in FIG. 2.

The SRAM cell 100 may in a row of an array of SRAM cells. Take the SRAM cell 100 as an example below to illustrate the operations and the circuit of the SRAM cell 100. The write-port circuit WP includes two p-type transistors, such as write-port pull-up (PU) transistors WPU1 and WPU2, and four n-type transistors, such as write-port pull-down (PD) transistors WPD1 and WPD2 and write-port pass-gate (PG) transistors WPG1 and WPG2. The write-port PU transistor WPU1, the write-port PU transistor WPU2, the write-port PD transistor WPD1, and the write-port PD transistor WPD2 form a cross latch having two cross-coupled inverters. The write-port PU transistor WPU1 and the write-port PD transistor WPD1 form a first inverter while the write-port PU transistor WPU2 and the write-port PD transistor WPD2 form a second inverter.

Drains of the write-port PU transistor WPU1 and the write-port PD transistor WPD1 are coupled together and form data node ND. Drains of the write-port PU transistor WPU2 and the write-port PD transistor WPD2 are coupled together and form data node NDB. Gates of the write-port PU transistor WPU1 and the write-port PD transistor WPD1 are coupled together and to drains of the write-port PU transistor WPU2 and the write-port PD transistor WPD2. Gates of the write-port PU transistor WPU2 and the write-port PD transistor WPD2 are coupled together and to drains of the write-port PU transistor WPU1 and the write-port PD transistor WPD1.

Sources of the write-port PU transistor WPU1 and the write-port PU transistor WPU2 are coupled together and to a supply voltage node NVDD. In some embodiments, the supply voltage nodes NVDD is configured to receive a supply voltage VDD. Source of the write-port PD transistor WPD1 is coupled with a reference voltage node NVSS1, and source of the write-port PD transistor WPD2 is coupled with a reference voltage node NVSS2. In some embodiments, reference voltage node NVSS1 and reference voltage node NVSS2 are electrically coupled together and configured to receive a reference voltage VSS.

The write-port PG transistor WPG1 functions as a pass gate between the data node ND and a write bit-line WBL, and the write-port PG transistor WPG2 functions as a pass gate between the data node NDB and a write bit-line-bar WBLB. A drain of the write-port PG transistor WPG1 is referred to as a write bit-line node NWBL and electrically coupled with the write bit-line WBL. A source of the write-port PG transistor WPG1 is electrically coupled with the data node ND. A drain of the write-port PG transistor WPG2 is referred to as a write bit-line-bar node NWBLB and electrically coupled with the write bit-line-bar WBLB. A source of the write-port PG transistor WPG2 is electrically coupled with the data node NDB. A gate of the write-port PG transistor WPG1 is referred to as a write word-line node NWWL1, a gate of the write-port PG transistor WPG2 is referred to as a write word-line node NWWL2, and write word-line nodes NWWL1 and NWWL2 are electrically coupled with a write word-line WWL.

In some embodiments, the write bit-line-bars WBLB and write bit-lines WBL are coupled to each drain of the write-port PG transistors WPG1 and WPG2 of memory cells in the same column of the array of the SRAM cells, and write word-line WWL is coupled to each gate of the write-port PG transistors WPG1 and WPG2 of memory cells in the same row of the array of the SRAM cells.

In a write operation of the SRAM cell 100 using the write-port circuit WP, data to be written to the SRAM cell 100 is applied to the write bit-line WBL and the write bit-line-bar WBLB. The write word-line WWL is then activated to turn on the write-port PG transistors WPG1 and WPG2. As a result, the data on the write bit-line WBL and the write bit-line-bar WBLB is transferred to and is stored in corresponding data nodes ND and NDB.

The read-port circuit RP includes two n-type transistors, such as read-port PD transistor RPD and read-port PG transistor RPG. A source of the read-port PD transistor RPD is coupled with a reference voltage node NVSS3. In some embodiments, the reference voltage node NVSS3 is configured to receive the reference voltage VSS. A gate of the read-port PD transistor RPD is coupled with the data node NDB and the gates of the write-port PU transistor WPU1 and the write-port PD transistor WPD1. A drain of the read-port PD transistor RPD is coupled with a source of the read-port PG transistor RPG. A drain of the read-port PG transistor RPG is referred to as a read bit-line node NRBL and electrically coupled with a read bit-line RBL. A gate of the read-port PG transistor RPG is referred to as a read word-line node NRWL and electrically coupled with a read word-line RWL.

In a read operation of the SRAM cell 100 using the read-port circuit RP, the read bit-line RBL is pre-charged with a high logical value. The read word-line RWL is activated with a high logical value to turn on the read-port PG transistor RPG. The data stored in data node NDB turns on or off the read-port PD transistor RPD. For example, if data node NDB stores a high logical value, the read-port PD transistor RPD is turned on. The turned-on read-port PG transistor RPG and the turned-on read-port PD transistor RPD then pull read bit-line RBL to the reference voltage VSS or a low logical value at the source of the read-port PD transistor RPD. On the other hand, if the data node NDB stores a low logical value, the read-port PD transistor RPD is turned off and operates as an open circuit. As a result, the read bit-line RBL remains at the pre-charged high logical value. Detecting a logical value on the read bit-line RBL therefore reveals the logical value stored in the data node NDB.

Although not shown in FIG. 2, in some embodiments, the gate of the read-port PD transistor RPD is coupled with the data node ND and the gates of the write-port PU transistor WPU2 and the write-port PD transistor WPD2. In such case, in the read operation of the SRAM cell 100 using the read-port circuit RP, the data stored in data node ND turns on or off the read-port PD transistor RPD. For example, if data node ND stores a high logical value, the read-port PD transistor RPD is turned on. The turned-on read-port PG transistor RPG and the turned-on read-port PD transistor RPD then pull read bit-line RBL to the reference voltage VSS or a low logical value at the source of the read-port PD transistor RPD. On the other hand, if the data node ND stores a low logical value, the read-port PD transistor RPD is turned off and operates as an open circuit. As a result, the read bit-line RBL remains at the pre-charged high logical value. Detecting a logical value on the read bit-line RBL therefore reveals the logical value stored in the data node ND.

In the present embodiments, adjacent two SRAM cells in the adjacent two rows are abutted with each other share the same read bit-line. In other words, the read bit-line node NRBL of the read-port PG transistor RPG of one SRAM cell 100 in one row and the read bit-line node NRBL of the read-port PG transistor RPG of another SRAM cell 100 in adjacent row are further coupled together and to the read bit-line RBL. In other word, two SRAM cells 100 share the read bit-line RBL. In some embodiments, the SRAM cell 100 shown in FIG. 2 has a total of eight transistors (including the write-port PU transistors WPU1 and WPU2, the write-port PD transistors WPD1 and WPD2, the write-port PG transistors WPG1 and WPG2, and the read-port PD transistors RPD and RPD), such that the SRAM cell 100 be referred to as 8T SRAM cell.

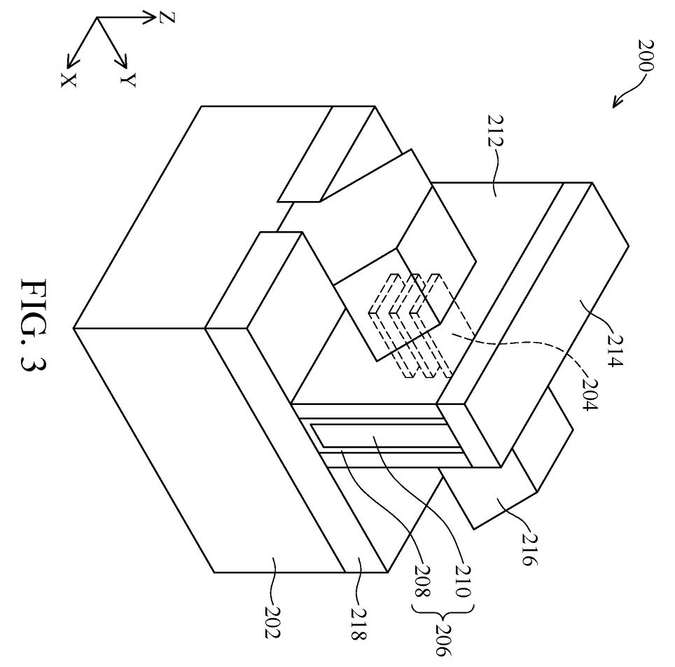

The SRAM cell 100 discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 3. However, it should be understood that the application should not be limited to a particular type of device, except as specifically claimed.

Referring to FIG. 3, a perspective view of an exemplary GAA transistor 200 is illustrated. The GAA transistor 200 is formed over a substrate 202. The substrate 202 may contains a semiconductor material, such as bulk silicon (Si).

The GAA transistor 200 also includes one or more nanostructures 204 (dash lines) extending in the Y-direction and vertically stacked (or arranged) in the Z-direction. More specifically, the nanostructures 204 are spaced apart from each other in the Z-direction. In some embodiments, the nanostructures 204 may also be referred to as channels, channel layers, nanosheets, or nanowires.

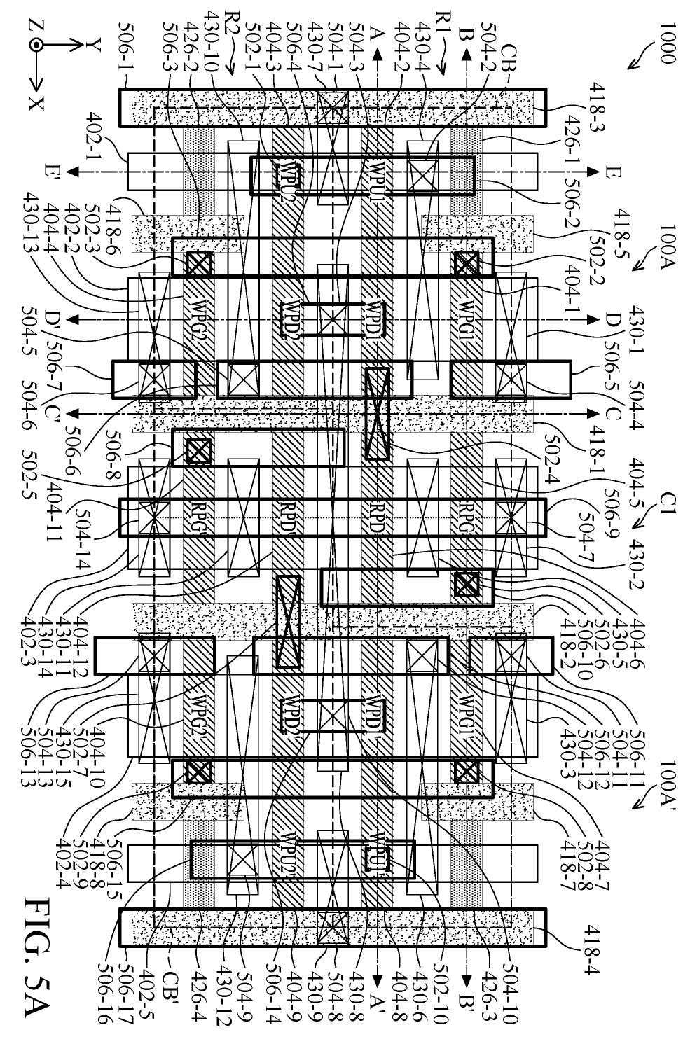

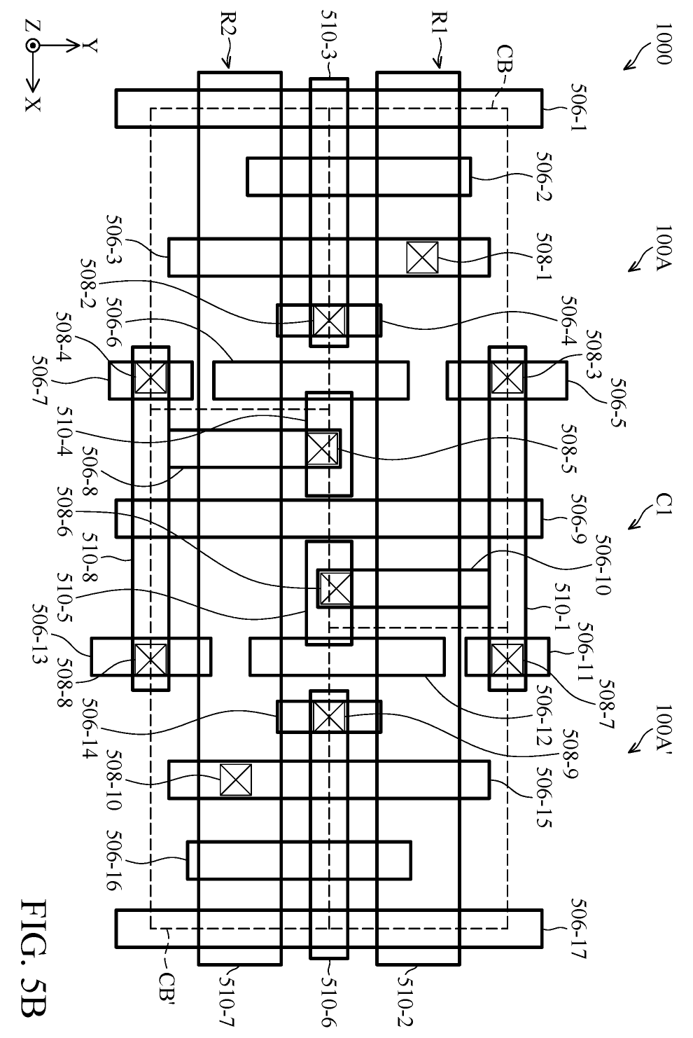

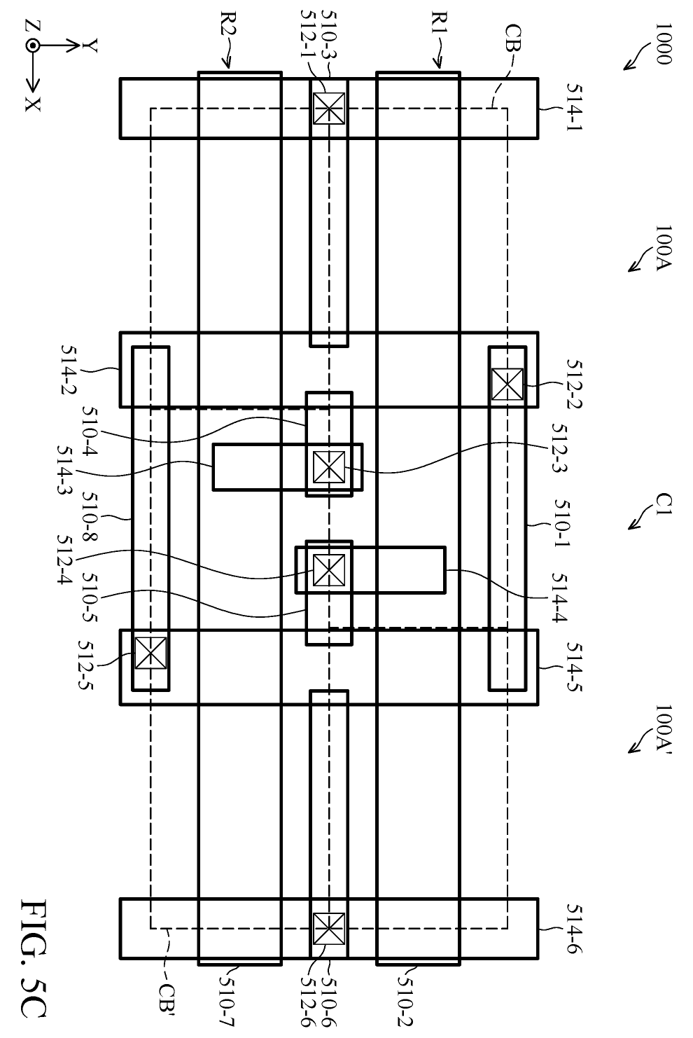

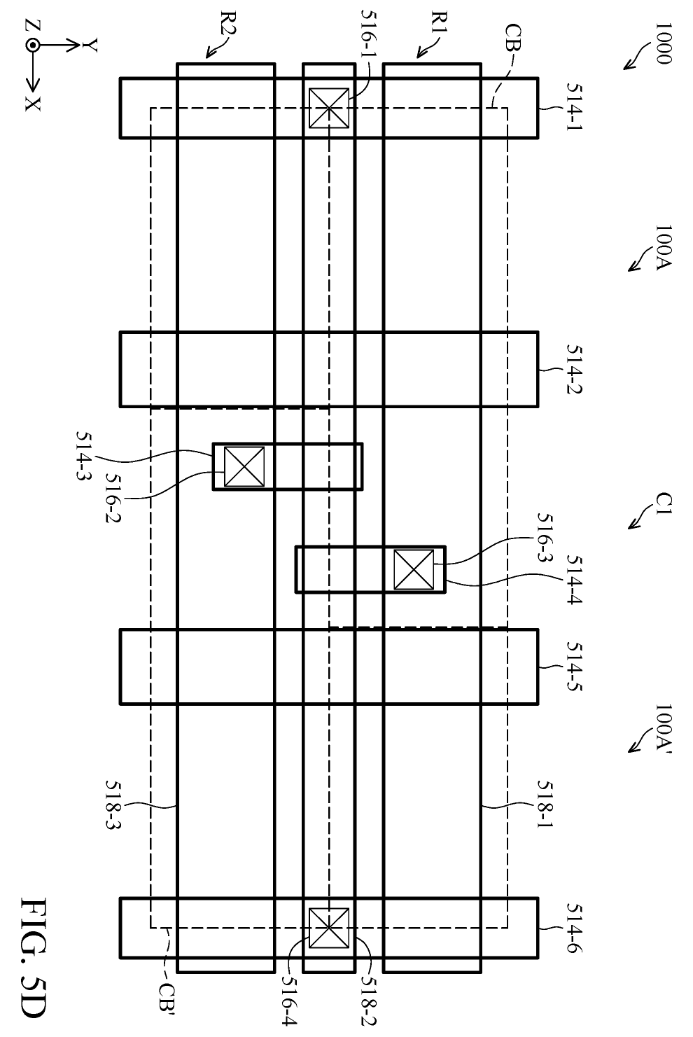

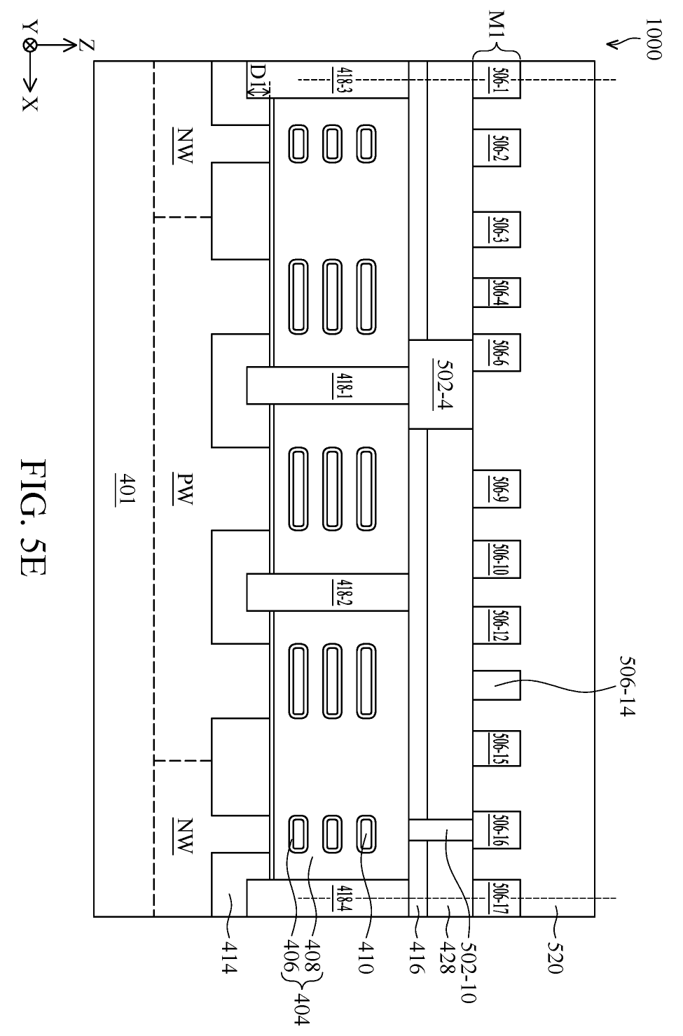

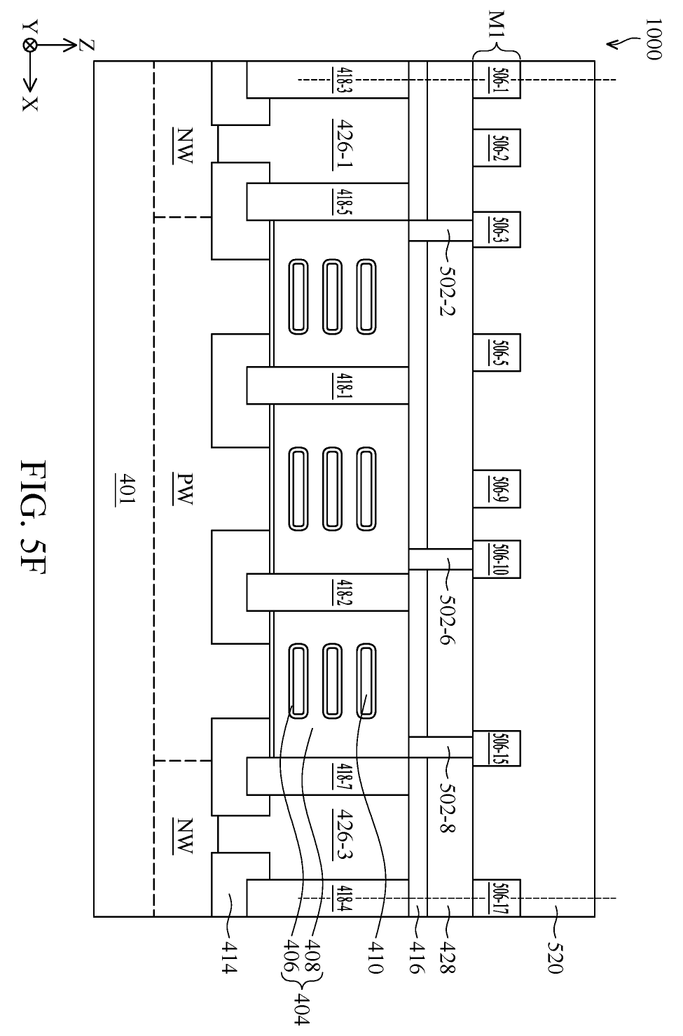

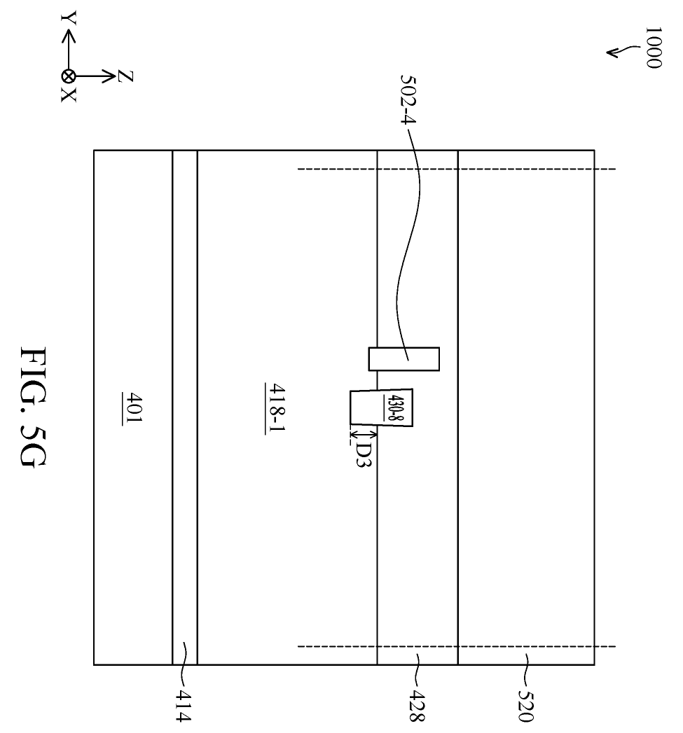

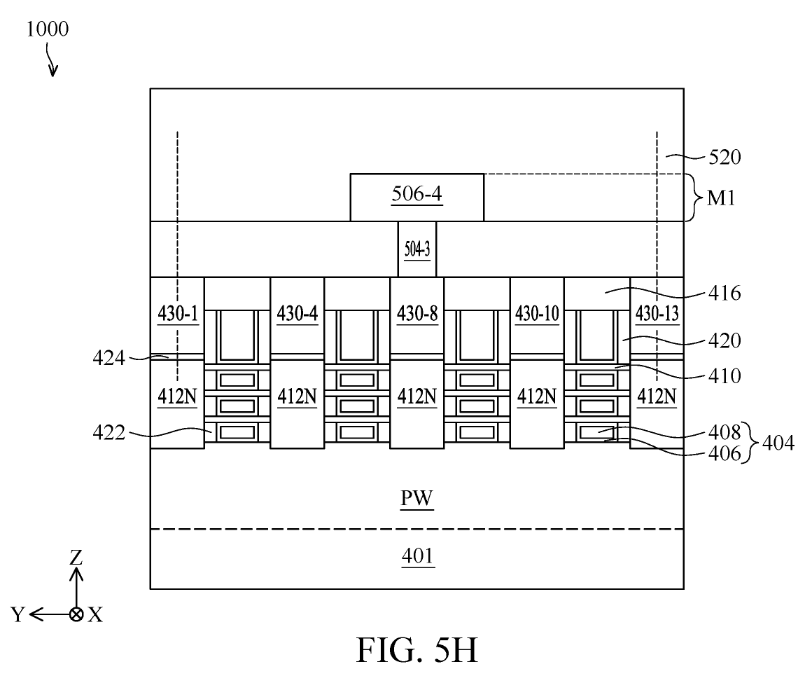

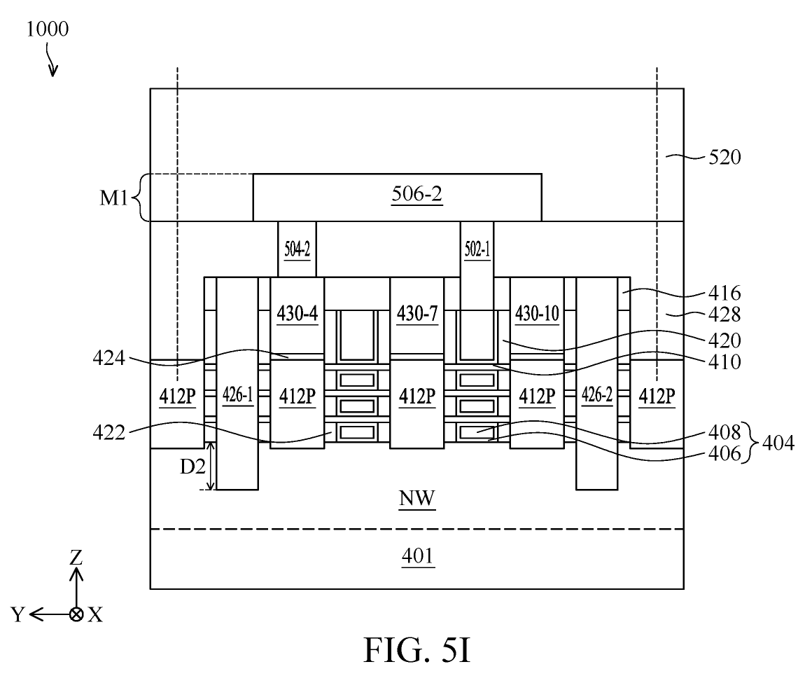

The GAA transistor 200 further includes a gate structure 206 including a gate dielectric layer 208 and a gate electrode 210. The gate dielectric layer 208 wraps around the nanostructures 204 and the gate electrode 210 wraps around the gate dielectric layer 208 (not shown in FIG. 3, may refer to FIGS. 5E, 5F, and 5H). As shown in FIG. 3, gate spacers 212 are on sidewalls of the gate structure 206 and over the nanostructures 204 (not shown in FIG. 3, may refer to FIG. 5H). A gate top dielectric layer 214 is over the gate dielectric layer 208, the gate electrode 210, and the nanostructures 204. The gate top dielectric layer 214 is used for contact etch protection layer.

The GAA transistor 200 further includes source/drain features 216. As shown in FIG. 3, two source/drain features 216 are on opposite sides of the gate structure 206. The nanostructures 204 (dash lines) extends in the Y-direction to connect one source/drain feature 216 to the other source/drain feature 216. The source/drain features 216 may also be referred to as source/drain, or source/drain regions. In some embodiments, source/drain feature(s) may refer to a source or a drain, individually or collectively dependent upon the context.

Isolation feature 218 is over the substrate 202 and under the gate dielectric layer 208, the gate electrode 210, and the gate spacers 212. The isolation feature 218 is used for isolating the GAA transistor 200 from other devices. In some embodiments, the isolation feature 218 may include different structures, such as shallow trench isolation (STI) structure, deep trench isolation (DTI) structure. Therefore, the isolation feature 218 is also referred as to as a STI feature or DTI feature.

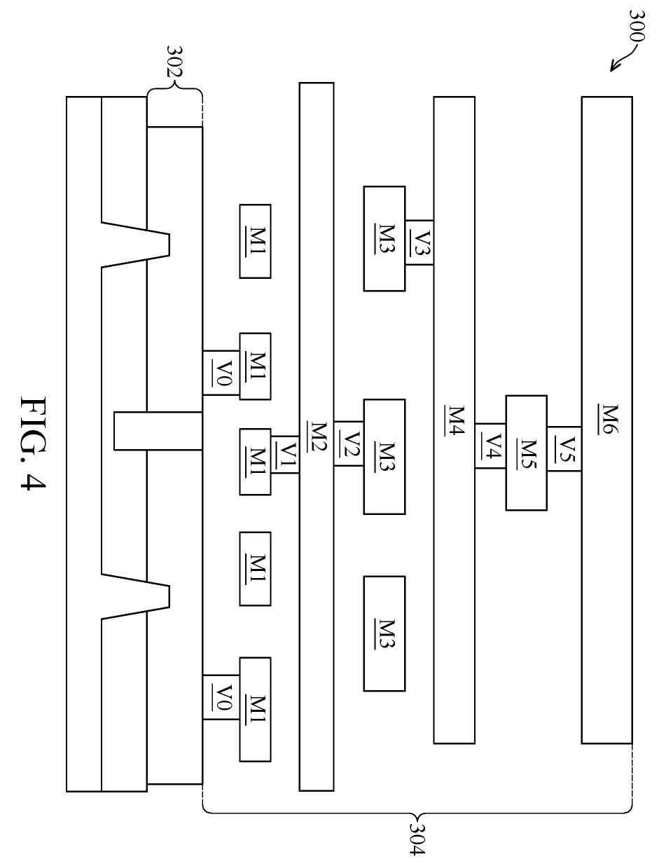

FIG. 4 shows a cross-sectional view of a semiconductor device 300 for illustrating an interconnection structure, in accordance with some embodiments of the present disclosure. The semiconductor device 300 has device region 302 (also referred to as a device layer) and an interconnection structure 304. The device region 302 is the region where the transistors and main features are located, such as gate, channel, source/drain, contact features, and the transistors (e.g., the transistors of the SRAM cell 100 discussed above) of the circuit cells discussed above. The interconnection structure 304 is over the device region 302 or at the front-side of the device region 302.

As shown in FIG. 4, the interconnection structure 304 includes a metal layer M1, a metal layer M2 over the metal layer M1, a metal layer M3 over the metal layer M2, a metal layer M4 over the metal layer M3, a metal layer M5 over the metal layer M4, and a metal layer M6 over the metal layer M5. Each of the metal layers M1, M2, M3, M4, M5, and M6 includes metal conductors. The interconnection structure 304 further includes vias V0, V1, V2, V3, V4, and V5 for connecting the metal conductor in the underlying metal layer to the metal conductor in the overlying metal layer. The vias and metal conductors electrically couple various transistors and/or components (for example, gate, source/drain features, resistors, capacitors, and/or inductors) in the device region 302, such that the various devices and/or components can operate as specified by the design requirements of circuit cells (e.g., logic cells and memory cells).

It should be noted that there may be more vias and metal conductors for connections. In some embodiments, some of the vias V0 are connected to the gate structures (gate electrodes) of the transistors. Therefore, such vias V1 connected to the gate structures are also referred to as the gate vias. In some embodiments, the vias and metal conductors are used for the connections of the features of the transistor. In other embodiments, the vias and metal conductors are connected to voltage sources (the supply voltage VDD or the reference voltage VSS discussed above) to provide voltage to the transistors in the device region 302. Therefore, the metal conductors connected to the voltage sources may be also referred to as the voltage metal conductors, the voltage lines, or voltage conductors.

For the operation speed of the read-port (e.g., the read-port PG of the SRAM cell 100) of the two-port SRAM cell is major dominated by transistor on-current and bit-line capacitance, in the present disclosure, the read bit-lines are designed to be located in the lowest metal layer (i.e., the metal layer M1) to have lower capacitance (save metal landing pad capacitance if located at higher metal layers). Further, since the read word-lines and the write word-lines are more care about resistance, the read word lines and the write word lines are designed to be located in the higher metal layer for having larger width.

Therefore, in some embodiments, the metal conductors serving as read bit-lines and VDD lines are designed to be located in the metal layer M1; the metal conductors serving as write word-lines are designed to be located in the metal layer M2; the metal conductors serving as write bit-lines and write bit-line-bars are designed to be located in the metal layer M3; and the metal conductors serving as read word-lines are designed to be located in the metal layer M4.

Furthermore, in other embodiments, the metal conductors serving as read bit-lines and VDD lines are designed to be located in the metal layer M1; the metal conductors serving as write bit-lines and write bit-line-bars are designed to be located in the metal layer M3; the metal conductors serving as write word-lines are designed to be located in the metal layer M4; and the metal conductors serving as read word-lines are designed to be located in the metal layer M6.

FIGS. 5A to 5D illustrate top views (or layouts) of two adjacent SRAM cells 100A and 100A’ in a portion of a array 1000 that can be one embodiment of the SRAM cells 100 in adjacent two rows implemented in the memory region 20, in accordance with some embodiments of the present disclosure. FIG. 5A illustrates the features in the device region (including transistors), the metal conductors in the first metal layer (M1), and vias (V0) vertically between the features and the first metal layer (M1). FIG. 5B illustrates the metal conductors in the first metal layer (M1) and the second metal layer (M2), and vias (V1) vertically between the first metal layer (M1) and the second metal layer (M2). FIG. 5C illustrates the metal conductors in the second metal layer (M2) and the third metal layer (M3), and vias (V2) vertically between the second metal layer (M2) and the third metal layer (M3). FIG. 5D illustrates the metal conductors in the third metal layer (M3) and the fourth metal layer (M4), and vias (V3) vertically between the third metal layer (M3) and the fourth metal layer (M4).

FIG. 5E is an X-Z cross-sectional view of the array 1000 along a line A-A’ in FIG. 5A, in accordance with some embodiments of the present disclosure. FIG. 5F is an X-Z cross-sectional view of the array 1000 along a line B-B’ in FIG. 5A, in accordance with some embodiments of the present disclosure. FIG. 5G is a Y-Z cross-sectional view of the array 1000 along a line C-C’ in FIG. 5A, in accordance with some embodiments of the present disclosure. FIG. 5H is a Y-Z cross-sectional view of the array 1000 along a line D-D’ in FIG. 5A, in accordance with some embodiments of the present disclosure. FIG. 5I is a Y-Z cross-sectional view of the array 1000 along a line E-E’ in FIG. 5A, in accordance with some embodiments of the present disclosure. For the sake of simplicity, FIGS. 5E to 5I shows the features in the device region, the metal conductors in the first metal layer (M1), and vias (V0) vertically between the features and the first metal layer (M1), while the vias and the metal conductors in higher metal layers (higher than the first metal layer (M1)) are omitted.

As shown in FIG. 5A to 5D, the array 1000 shows a row R1 having the SRAM cells 100A which is abutted and adjacent to the SRAM cells 100A’ in a row R2. More specifically, the adjacent two SRAM cells 100A and 100A’ are respectively in the adjacent two rows R1 and R2, and are together in a column C1.

The SRAM cells 100A and 100A’ each respectively has a cell boundary CB and a cell boundary CB’. Each of the cell boundaries CB and CB’ has a non-rectangular shape (indicated by the dotted rectangular box). More specifically, each of the cell boundaries CB and CB’ is L-shaped in a top view (or an X-Y plane view), as shown in FIG. 5A to 5D. Therefore, in some embodiments, the cell boundaries CB and CB’ may be referred to as non-rectangular cell boundaries or L-shaped cell boundaries. The SRAM cells 100A and 100A’ are abutted together such the cell boundary CB abuts the cell boundary CB’ to form a rectangular shape.

The array 1000 includes active areas, such as active areas 402-1 to 402-5, (may be collectively referred to as the active areas 402) that extend lengthwise in the Y-direction and are arranged in the X-direction. The active areas 402-1 and 402-2 are used for the SRAM cell 100A; the active areas 402-4 and 402-5 are used for the SRAM cell 100A’; and the active area 402-3 is shared by the SRAM cells 100A and 100A’. Each of active areas 402 includes channel regions, source regions, and drain regions (where source regions and drain regions are collectively referred to as source/drain regions herein) of transistors.

The array 1000 further includes gate structures, such as gate structures 404-1 to 404-15 (may be collectively referred to as the gate structures 404) that extend lengthwise in the X-direction. The X-direction and the Y-direction are perpendicular. The gate structures 404-1 to 404-12 are disposed over the channel regions of the respective active areas 402-1 to 402-5 (i.e., (vertically stacked) nanostructures 410) and disposed between respective source/drain regions of the active areas 402-1 to 402-5 (i.e., source/drain features 412N and 412P). In some embodiments, the gate structures 404-1 to 404-12 wrap and/or surround suspended, vertically stacked nanostructures 410 in the channel regions of the active areas 402-1 to 402-5, respectively (as shown in FIGS. 5E, 5F, and 5H).

In the SRAM cell 100A, the gate structure 404-1 extends across the active area 402-2 in the top view and engages the active area 402-2 to form the write-port PG transistor WPG1; the gate structure 404-2 extends across the active areas 402-1 and 402-2 in the top view and engages the active area 402-1 and 402-2 to respectively form the write-port PU transistor WPU1 and the write-port PD transistor WPD1; the gate structure 404-3 extends across the active areas 402-1 and 402-2 in the top view and engages the active areas 402-1 and 402-2 to respectively form the write-port PU transistor WPU2 and the write-port PD transistor WPD2; the gate structure 404-4 extends across the active area 402-2 in the top view and engages the active area 402-2 to form the write-port PG transistor WPG2; the gate structure 404-5 extends across the active area 402-3 in the top view and engages the active area 402-3 to form the read-port PG transistor RPG; and the gate structure 404-6 extends across the active area 402-3 in the top view and engages the active area 402-3 to form the read-port PG transistor RPD.

In the SRAM cell 100A’, the gate structure 404-7 extends across the active area 402-4 in the top view and engages the active area 402-4 to form the write-port PG transistor WPG1’; the gate structure 404-8 extends across the active areas 402-5 and 402-4 in the top view and engages the active area 402-5 and 402-4 to respectively form the write-port PU transistor WPU1’ and the write-port PD transistor WPD1’; the gate structure 404-9 extends across the active areas 402-5 and 402-4 in the top view and engages the active areas 402-5 and 402-4 to respectively form the write-port PU transistor WPU2’ and the write-port PD transistor WPD2’; the gate structure 404-10 extends across the active area 402-4 in the top view and engages the active area 402-4 to form the write-port PG transistor WPG2’; the gate structure 404-11 extends across the active area 402-3 in the top view and engages the active area 402-3 to form the read-port PG transistor RPG’; and the gate structure 404-12 extends across the active area 402-3 in the top view and engages the active area 402-3 to form the read-port PG transistor RPD’.

As shown in FIG. 5A, the write-port PU transistor WPU1 and the write-port PU transistor WPU2 are arranged in the Y-direction and share the active area 402-1; the write-port PG transistor WPG1, the write-port PD transistor WPD1, the write-port PD transistor WPD2, and the write-port PG transistor WPG2 are arranged in the Y-direction and share the active area 402-2; the read-port PG transistor RPG, the read-port PD transistor RPD, the read-port PD transistor RPD’, and the read-port PG transistor RPG’ are arranged in the Y-direction and share the active area 402-3; the write-port PG transistor WPG1’, the write-port PD transistor WPD1’, the write-port PD transistor WPD2’, and the write-port PG transistor WPG2’ are arranged in the Y-direction and share the active area 402-4; and the write-port PU transistor WPU1’ and the write-port PU transistor WPU2’ are arranged in the Y-direction and share the active area 402-5.

Similar to the substrate 202 discussed above, the array 1000 further includes substrate 401, over which the various features are formed, such as the gate structures 404-1 to 404-12. The substrate 401 may contains a semiconductor material, such as bulk silicon (Si). In some other embodiments, the substrate 401 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Alternatively, the substrate 401 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

In some embodiments, the n-type well NW and p-type wells PW are formed in or on the substrate 401, as shown in FIGS. 5E to 5I. In the present embodiment, the p-type wells PW are p-type doped regions configured for n-type transistors (e.g., the write-port PG transistors WPG1, WPG2, WPG1’, and WPG2’, the write-port PD transistors WPD1, WPD2, WPD1’, and WPD2’, the read-port PG transistors RPG and RPG’, and the read-port PD transistors RPD and RPD’), and the n-type well NW are n-type doped regions configured for p-type transistors (e.g., the write-port PU transistors WPU1, WPU2, WPU1’, and WPU2’). The n-type well NW is doped with n-type dopants, such as phosphorus, arsenic, other n-type dopant, or a combination thereof. The p-type wells PW are doped with p-type dopants, such as boron, indium, other p-type dopant, or a combination thereof. In some implementations, the substrate 401 includes doped regions formed with a combination of p-type dopants and n-type dopants. The various n-type wells and/or p-type wells can be formed directly on and/or in the substrate 401, for example, providing a p-well structure, an n-well structure, a dual-well structure, a raised structure, or a combination thereof. An ion implantation process, a diffusion process, and/or other suitable doping process can be performed to form the various wells.

Similar to the isolation feature 218 discussed above, the array 1000 further includes an isolation feature (or isolation structure) 414. The isolation feature 414 may include silicon oxide, silicon nitride, silicon oxynitride, other suitable isolation material (for example, including silicon, oxygen, nitrogen, carbon, or other suitable isolation constituent), or combinations thereof. The isolation feature 414 may include different structures, such as shallow trench isolation (STI) structures, deep trench isolation (DTI) structures, and/or local oxidation of silicon (LOCOS) structures. In some embodiments, STI features include a multi-layer structure that fills the trenches, such as a silicon nitride comprising layer disposed over a thermal oxide comprising liner layer. In another example, STI features include a dielectric layer disposed over a doped liner layer (including, for example, boron silicate glass (BSG) or phosphosilicate glass (PSG)). In yet another example, STI features include a bulk dielectric layer disposed over a liner dielectric layer, where the bulk dielectric layer and the liner dielectric layer include materials depending on design requirements.

Each of the transistors in the SRAM cell 100A (e.g., the write-port PG transistors WPG1 and WPG2, the write-port PD transistors WPD1 and WPD2, the write-port PU transistors WPU1 and WPU2, the read-port PG transistor RPG, and the read-port PD transistor RPD) and the transistors in the SRAM cell 100A’ (e.g., the write-port PG transistors WPG1’ and WPG2’, the write-port PD transistors WPD1’ and WPD2’, the write-port PU transistors WPU1’ and WPU2’, the read-port PG transistor RPG’, and the read-port PD transistor RPD’) includes nanostructures 410 similar to the nanostructures 204 discussed above. As shown in FIGS. 5E, 5F, 5H, and 5I, the nanostructures 410 are suspended. In some embodiments, three nanostructures 410 are vertically stacked (or vertically arranged) from each other in the Z-direction for one transistor. However, there may be another appropriate number of nanostructures in one transistor. For example, there may be from 2 to 6 nanostructures 410 in one transistor.

The nanostructures 410 further extend lengthwise in the Y-direction (FIGS. 5E and 5F) and widthwise in the X-direction (FIGS. 5H and 5I). In some embodiments, a width of the nanostructures 410 in the active area 402-3 in the X-direction is greater than a width of the nanostructures 410 in the active areas 402-2 and 402-4, and the width of the nanostructures 410 in the active areas 402-2 and 402-4 is greater than a width of the nanostructures 410 in the active areas 402-1 and 402-5, as shown in FIGS. 5A and 5E. As shown in FIG. 5E, in each of the transistors in the SRAM cell 100A and 100A’, three nanostructures 410 are spaced apart from each other in the Z-direction.

The nanostructures 410 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 410 include silicon for n-type transistors, such as the write-port PD transistors WPD1, WPD2, WPD1’, and WPD2’, the write-port PG transistors WPG1, WPG2, WPG1’, and WPG2’, the read-port PD transistors RPD and RPD’, and the read-port PG transistors RPG and RPG’. In other embodiments, the nanostructures 410 include silicon germanium for p-type transistors, such as the write-port PU transistors WPU1, WPU2, WPU1’, and WPU2’. In some embodiments, the nanostructures 410 are all made of silicon, and the type of the transistors depend on work function metal layer wrapping around the nanostructures 410. In some embodiments, the nanostructures 410 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

Each of the gate structures 404-1 to 404-12 has a gate dielectric layer 406 and a gate electrode layer 408. The gate dielectric layers 406 wrap around each of the nanostructures 410, and the gate electrodes layer 408 wrap around the gate dielectric layer 406 and the nanostructures 410. In some embodiments, the gate structures 404 each further includes an interfacial layer (such as having silicon dioxide, silicon oxynitride, or other suitable materials) between the gate dielectric layer 406 and the nanostructures 410.

The gate dielectric layers 406 may include oxide with nitrogen doped dielectric material (initial layer) combined with metal content high-K dielectric material (K value (dielectric constant) >13). For example, gate dielectric layers 406 may include hafnium oxide (HfO₂), which has a dielectric constant in a range from about 18 to about 40. Alternatively, the gate dielectric layers 406 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 406 may be formed by chemical oxidation, thermal oxidation, ALD, CVD, and/or other suitable methods.

The gate electrode layer 408 is formed to wrap around the gate dielectric layer 406 and the center portions of the nanostructures 410, as shown in FIGS. 5H and 5I. In some embodiments, the gate electrode layer 408 may include an n-type work function metal layer for n-type transistor (such as the write-port PD transistors WPD1, WPD2, WPD1’, and WPD2’, the write-port PG transistors WPG1, WPG2, WPG1’, and WPG2’, the read-port PD transistors RPD and RPD’, and the read-port PG transistors RPG and RPG’) or a p-type work function metal layer for p-type transistor (such as the write-port PU transistors WPU1, WPU2, WPU1’, and WPU2’).

More specifically, each of the gate electrode layers 408 may have n-type work function metal layers between the source/drain features 412N with an n-type dopant for an n-type transistor (such as the write-port PD transistors WPD1, WPD2, WPD1’, and WPD2’, the write-port PG transistors WPG1, WPG2, WPG1’, and WPG2’, the read-port PD transistors RPD and RPD’, and the read-port PG transistors RPG and RPG’) and p-type work function metal layers between the source/drain features 412P with a p-type dopant for a p-type transistor (such as the write-port PU transistors WPU1, WPU2, WPU1’, and WPU2’), in accordance with some embodiments of the present disclosure.

In an embodiment, the n-type work function metal layer is a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

In an embodiment, the p-type work function metal layer is a material such as TiN, TaN, Ru, Mo, Al, WN, ZrSi2, MoSi2, TaSi2, NiSi2, WN, other metal oxides, metal nitrides, metal silicates, transition metal-oxides, transition metal-nitrides, transition metal-silicates, oxynitrides of metals, metal aluminates, zirconium silicate, zirconium aluminate, other suitable p-type work function materials, combinations of these, or the like. Additionally, the p-type work function metal layer may be deposited using a deposition process such as ALD, CVD, or the like, although any suitable deposition process may be used.

In some embodiments, the gate electrode layer 408 may include a single layer or alternatively a multi-layer structure. In some embodiments, the gate electrode layer 408 may further include a capping layer, a barrier layer, and a fill material (not shown). The capping layer may be formed adjacent to the gate dielectric layers 406 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The SRAM cells 100A and 100A’ further include gate spacers 420 are on sidewalls of the gate structures 404 and over the nanostructures 410, as shown in FIGS. 5H and 5I. More specifically, the gate spacers 420 are over the nanostructures 410 and on top sidewalls of the gate structures 404, and thus are also referred to as gate top spacers or top spacers. The gate spacers 420 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 420 may include a single layer or a multi-layer structure.

As shown in FIGS. 5H and 5I, the SRAM cells 100A and 100A’ further include inner spacers 422 on the sidewalls of the gate structures 404 and below the topmost nanostructures 410 and the gate spacers 420. Furthermore, the inner spacers 422 are laterally between the source/drain features 412N (or 412P) and the gate structures 404. The inner spacers 422 are also vertically between adjacent nanostructures 410. The inner spacers 422 may include a dielectric material having higher K value (dielectric constant) than the gate spacers 420 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In some embodiments, the thickness of the gate spacers 420 in the Y-direction and the thickness of the inner spacers 422 in the Y-direction are the same. In other embodiments, the thickness of the gate spacers 420 in the Y-direction is less than the thickness of the inner spacers 422 in the Y-direction due to the gate spacers 420 are trimmed during processes for forming source/drain contacts.

Referring to FIGS. 5H and 5I, the SRAM cells 100A and 100A’ further include source/drain features 412N and source/drain features 412P in the source/drain regions of the active areas 402. The source/drain features 412N are disposed on opposite sides of the respective gate structure 404 and connected by the nanostructures 410 to form n-type transistor (e.g., the write-port PD transistors WPD1, WPD2, WPD1’, and WPD2’, the write-port PG transistors WPG1, WPG2, WPG1’, and WPG2’, the read-port PD transistors RPD and RPD’, and the read-port PG transistors RPG and RPG’). Similarly, the source/drain features 412P are disposed on opposite sides of the respective gate structure 404 and connected by the nanostructures 410 to form p-type transistor (e.g., the write-port PU transistors WPU1, WPU2, WPU1’, and WPU2’). In some aspects, the source/drain features 412N/412P are disposed on opposite sides of the respective nanostructures 410. More specifically, the source/drain features 412N/412P are attached and electrically connected to the nanostructures 410 in the Y-direction, as shown in FIGS. 5H and 5I. Furthermore, every two adjacent transistors in the Y direction share one source/drain feature 412N/412P, as shown in FIG. 5A, 5H, and 5I.

The source/drain features 412N and 412P may be formed by using an epitaxial growth process. In some embodiments, the source/drain features 412N may include epitaxially-grown material selected from a group consisting of SiP, SiC, SiPC, SiAs, Si, or a combination thereof. In some embodiments, the epitaxially-grown material of the source/drain features 412N may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 412N for n-type transistors may be respectively referred to as n-type features and n-type source/drain features.

In some embodiments, the source/drain features 412P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 412P may be doped with p-type dopants (such as boron, indium, other p-type dopant, or combinations thereof) having a doping concentration in a range from about 1×10¹⁹/cm³ to 6×10²⁰/cm³. In some embodiments, the source/drain features 412P for p-type transistors may be respectively referred to as p-type source/drain features.

Referring to FIGS. 5A to 5G, the SRAM cells 100A and 100A’ further include gate end dielectric structures 418-1 to 418-8 (may be collectively referred to as the gate end dielectric structures 418) at ends of the gate structures 404. The gate end dielectric structures 418 extend lengthwise in the Y-direction. As shown in FIG. 5A, the gate end dielectric structure 418-1 is between the active areas 402-2 and 402-3, and the gate end dielectric structure 418-2 is between the active areas 402-4 and 402-3. Furthermore, the gate end dielectric structures 418-5 and 418-6 are between the active areas 402-1 and 402-2, and the gate end dielectric structures 418-7 and 418-8 are between the active areas 402-5 and 402-4.

The gate end dielectric structures 418 are used for separating the gate structures 404 aligned in the X-direction. For examples, the gate end dielectric structure 418-1 is between and separates the gate structure 404-1 and the gate structure 404-5 in the X-direction, the gate structure 404-2 and the gate structure 404-6 in the X-direction, separates the gate structure 404-3 and the gate structure 404-12 in the X-direction, and the gate structure 404-4 and the gate structure 404-11 in the X-direction. The gate end dielectric structure 418-2 is between and separates the gate structure 404-7 and the gate structure 404-5 in the X-direction, the gate structure 404-8 and the gate structure 404-6 in the X-direction, the gate structure 404-9 and the gate structure 404-12 in the X-direction, and the gate structure 404-10 and the gate structure 404-11 in the X-direction. Furthermore, as shown in FIGS. 5A, 5E, and 5F, the gate end dielectric structure 418-1 is in contact with the gate structures 404-1, 404-2, 404-3, 404-4, 404-5, 404-6, 404-12, and 404-11 in the X-direction, and the gate end dielectric structure 418-2 is in contact with the gate structures 404-7, 404-8, 404-9, 404-10, 404-5, 404-6, 404-12, and 404-11 in the X-direction.

As shown in FIG. 5A, the gate end dielectric structures 418-1 and 418-2 are between the write-port and the read-port of each of the SRAM cells 100A and 100A’ in the X-direction. More specifically, in the SRAM cell 100A, the gate end dielectric structure 418-1 separate the write-port PG transistors WPG1 and WPG2 and the write-port PD transistors WPD1 and WPD2 in the write-port and the read-port PG transistor RPG and the read-port PD transistor RPD in the read-port. In the SRAM cell 100A’, the gate end dielectric structure 418-2 separate the write-port PG transistors WPG1’ and WPG2’ and the write-port PD transistors WPD1’ and WPD2’ in the write-port and the read-port PG transistor RPG’ and the read-port PD transistor RPD’ in the read-port.

The gate end dielectric structures 418-3 and 418-4 are used for separating the abutted SRAM cells 100A and 100A’ from other device (e.g., SRAM cells or logic cells) in the X-direction. As shown in FIG. 5A, the gate end dielectric structure 418-3 lengthwise overlaps the (L-shaped) cell boundary CB and the gate end dielectric structure 418-4 lengthwise overlaps the (L-shaped) cell boundary CB’. Furthermore, as shown in FIGS. 5A, 5E, and 5F, the gate end dielectric structure 418-3 is in contact with the gate structures 404-2 and 404-3 and dielectric gate structures 426-1 and 426-2 (discussed below) in the X-direction, and the gate end dielectric structure 418-4 is in contact with the gate structures 404-8 and 404-9 and the dielectric gate structures 426-3 and 426-4 (discussed below) in the X-direction.

As shown in FIGS. 5E and 5F, the gate end dielectric structures 418 further extend into the isolation features 414 in the Z-direction. In some embodiments, bottom surfaces of the gate end dielectric structures 418 are lower than bottom surfaces of the gate structures 404, topmost surfaces of the substrate 401, and top surfaces of the isolation feature 414, as shown in FIGS. 5E and 5F. Furthermore, each of the gate end dielectric structures 418 has a depth D1 that extends into the isolation features 414 in a range from about 5 nm to about 60 nm, as shown in FIG. 5E. In other words, distances from the bottom surfaces of the gate end dielectric structures 418 to the than the bottom surfaces of the gate structures 404, the topmost surfaces of the substrate 401, and the top surfaces of the isolation feature 414 are in a range from about 5 nm to about 60 nm, as shown in FIG. 5E.

It is noted that the gate end dielectric structures 418-1 to 418-4 are continuous gate end dielectric structures to extend in the Y-direction across whole SRAM cells 100A and 100A’. More specifically, the gate end dielectric structures 418-1 to 418-4 are continuous to extend across SRAM cells in the same column in the array 1000. One advantage of such continuous gate end dielectric structures is that the process window of the formation of the gate structures 404 and the source/drain features 412N and 412P are increased. The gate end dielectric structures 418 are formed after the formation of the gate structures 404 and the source/drain features 412N and 412P. Before the formation of the gate structures 404 discussed above, the gate structures 404 aligned in the X-direction may be originally one continuous gate structure extending in the X-direction. In other words, the gate structures 404 aligned in the X-direction may be formed from one continuous gate structure in the X-direction. For examples, the gate structures 404-2, 404-6, and 404-8 are originally one continuous gate structure extending in the X-direction, and then the gate end dielectric structures 418-1 and 418-2 are formed to cut the continuous gate structure into the gate structures 404-2, 404-6, and 404-8. Such way for forming the gate structures 404 are more precise and have larger process window.

Similarly, the source/drain features 412N/412P aligned in the X-direction can be originally formed to merge together. Then, the gate end dielectric structures 418 are formed to cut the merged source/drain features into the source/drain features 412N/412P discussed above. Such way for forming the source/drain features 412N/412P does not need to concern and control the volume of the source/drain features 412N/412P and have larger process window. Furthermore, the source/drain features 412N/412P can be formed in such way have a larger length in the X-direction, thereby reducing the resistance. Although not shown in FIGS. 5A to 5I, the source/drain features 412N/412P are in contact with the gate end dielectric structures 418 in the X-direction, in accordance with some embodiments.

The material of the gate end dielectric structures 418 can be single dielectric layer or multiple layers and selected from a group consisting of Si₃N₄, nitride based dielectric layer, SiO₂, SiOC, SiON, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y2O3), multiple metal content oxide, or combinations thereof.

The SRAM cells 100A and 100A’ further include gate top dielectric layers 416 are over the gate dielectric layers 406, the gate electrode layers 408, and the nanostructures 410. The gate top dielectric layers 416 are similar to the gate top dielectric layer 214 discussed above. The gate top dielectric layer 416 is used for contact etch protection layer. The material of gate top dielectric layer 416 is selected from a group consisting of oxide, SiOC, SiON, SiOCN, nitride base dielectric, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), combinations thereof, or other suitable material.

Referring to FIGS. 5A to 5G, the SRAM cells 100A and 100A’ further include dielectric gate structures 426-1 to 426-4 (may be collectively referred to as the dielectric gate structures 426) for cutting the active areas 402-1 and 402-5. As shown in FIG. 5A, the active areas 402-1 and 402-5 are continuous to extend across the entirety of the array 1000 in the Y-direction. The dielectric gate structures 426-1 to 426-4 are formed to cut the active areas 402-1 and 402-5, such that the write-port PU transistors WPU1, WPU2, WPU1’, and WPU2’ are electrically isolated from the other write-port PU transistors in other SRAM cells in adjacent rows.

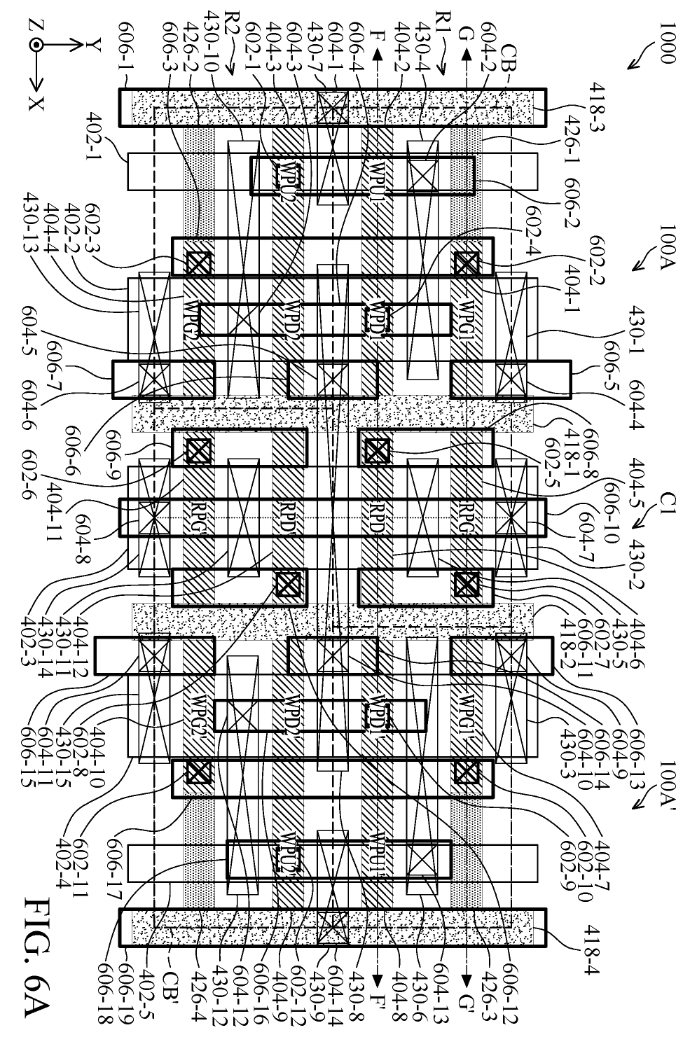

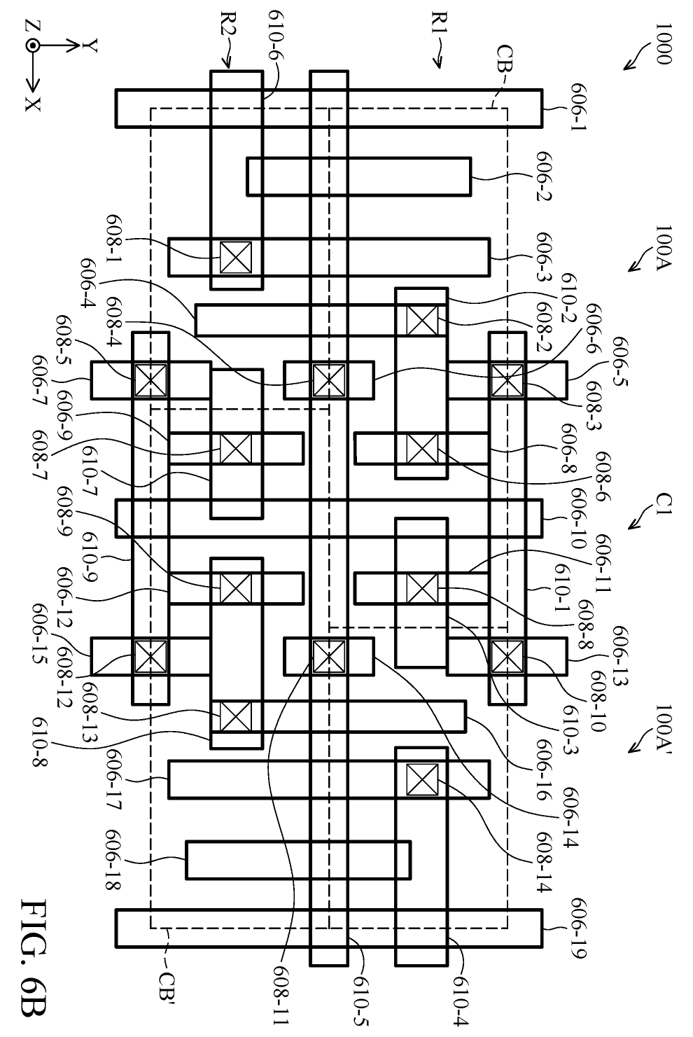

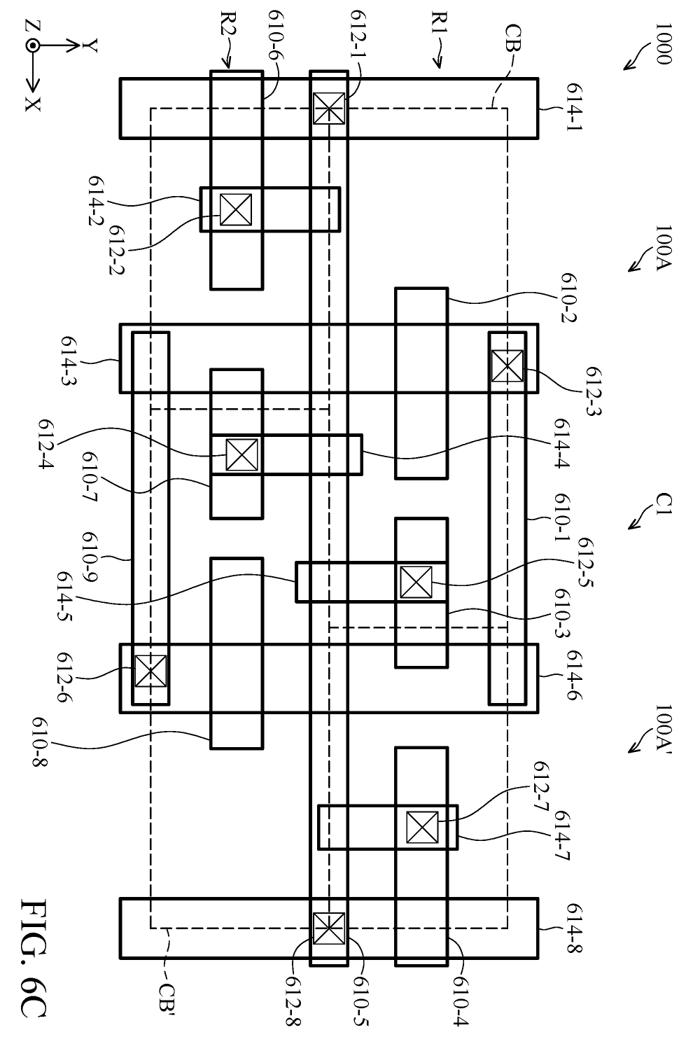

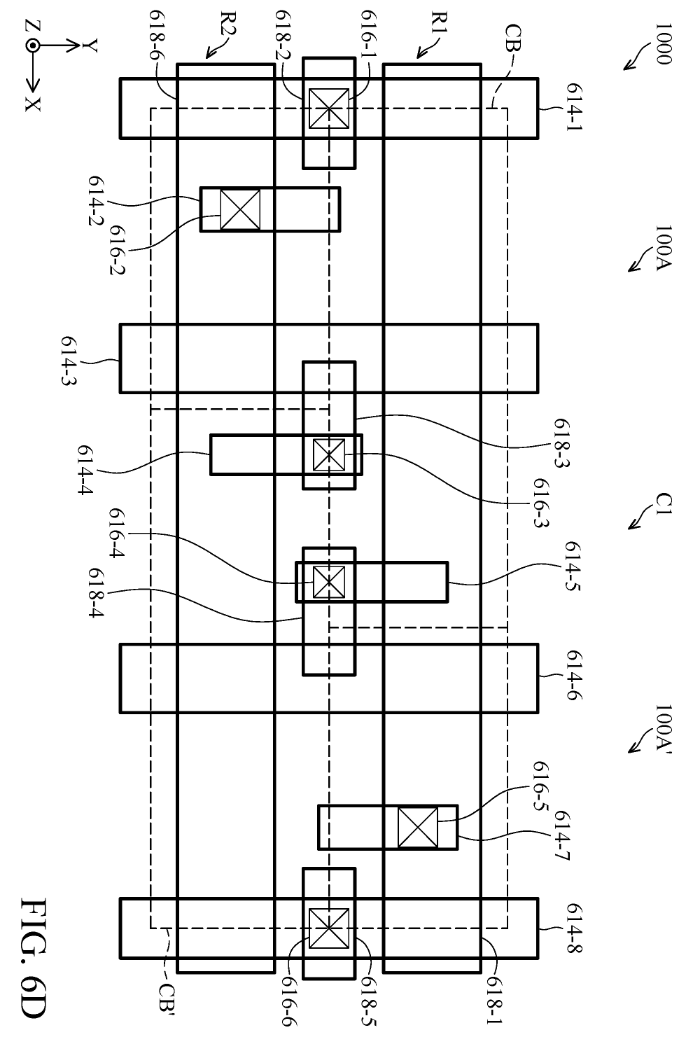

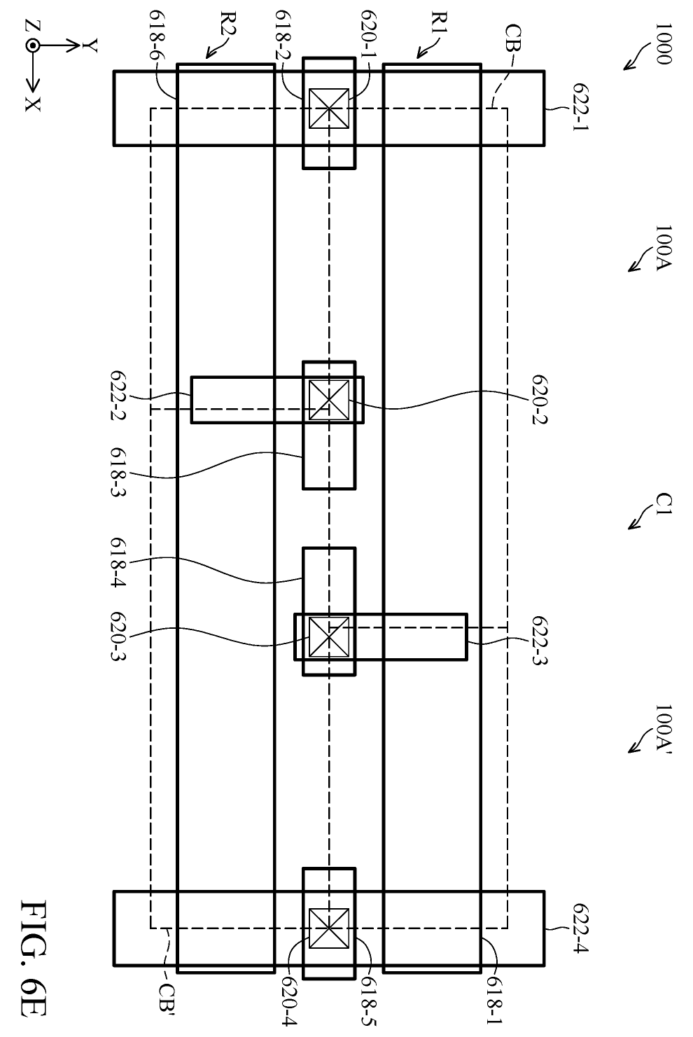

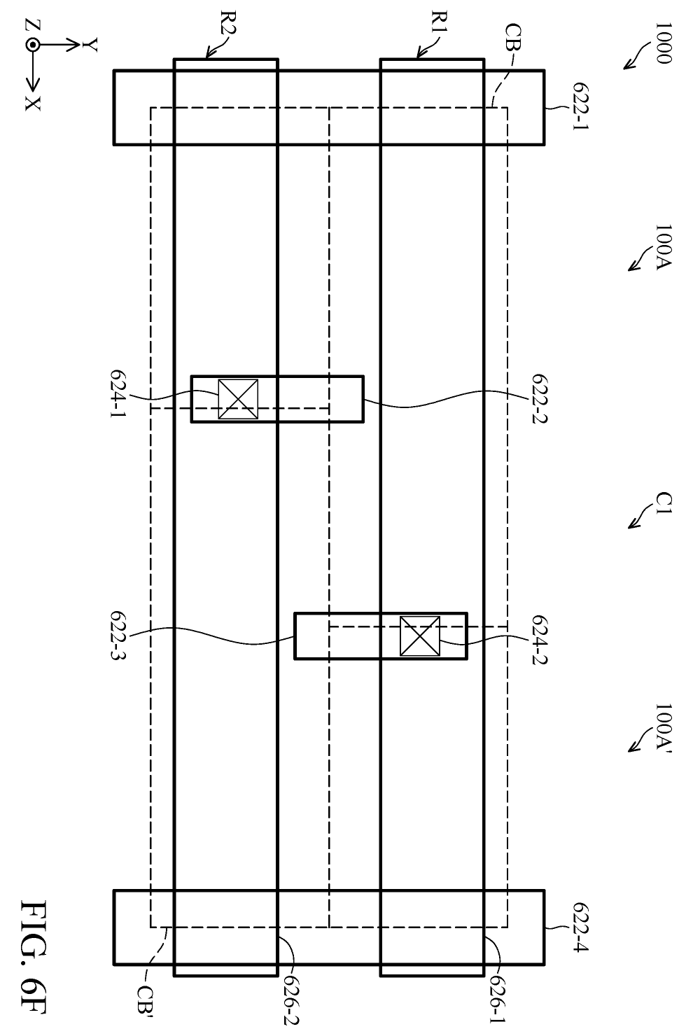

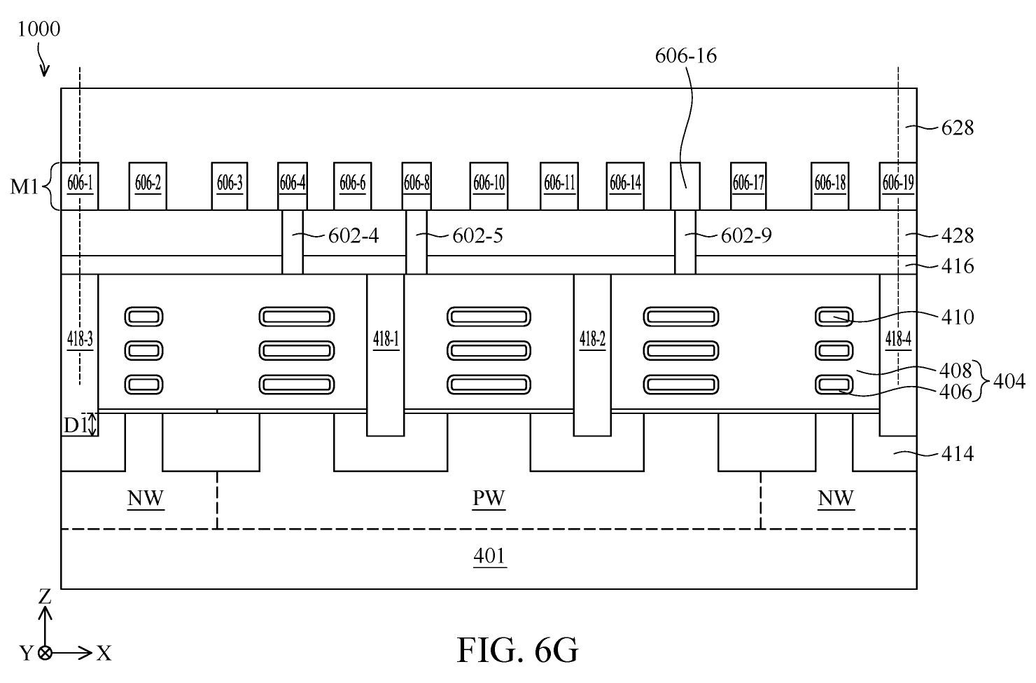

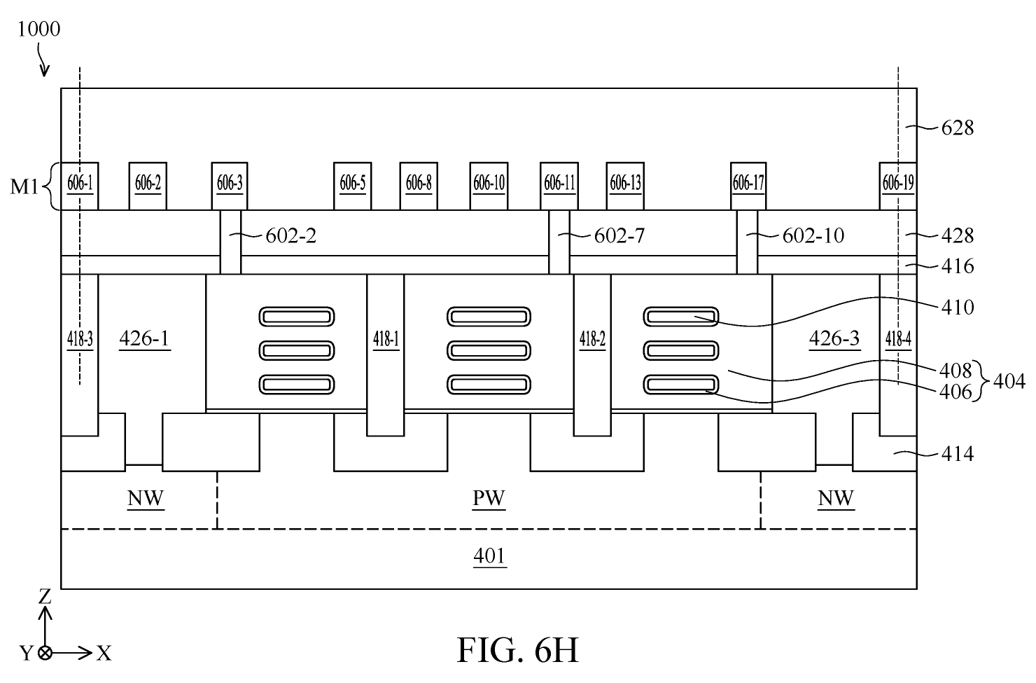

The dielectric gate structures 426 extend lengthwise in the X-direction. As shown in FIG. 5A, the dielectric gate structure 426-1, the write-port PU transistor WPU1, the write-port PU transistor WPU2, and dielectric gate structure 426-2 are arranged in the Y-direction; and the dielectric gate structure 426-3, the write-port PU transistor WPU1’, the write-port PU transistor WPU2’, and the dielectric gate structure 426-4 are arranged in the Y-direction. In some embodiments, the gate end dielectric structures 418-5 to 418-8 are optional and the dielectric gate structures 426-1, 426-2, 426-3, and 426-4 are respectively aligned and in contact with the gate structures 404-1, 404-4, 404-7, and 404-10 in the X-direction (not shown in FIG. 5A and 5F, may refer to FIGS. 6A and 6H).

As shown in FIGS. 5A and 5F, the gate end dielectric structures 418-5, 418-6, 418-7, and 418-8 respectively separate the dielectric gate structures 426-1, 426-2, 426-3, and 426-4 from the gate structures 404-1, 404-4, 404-7, and 404-10 in the X-direction. Furthermore, as shown in FIGS. 5A and 5F, the dielectric gate structure 426-1 is between and in contact with the gate end dielectric structure 418-3 and 418-5, the dielectric gate structure 426-2 is between and in contact with the gate end dielectric structure 418-3 and 418-6, the dielectric gate structure 426-3 is between and in contact with the gate end dielectric structure 418-4 and 418-7, and the dielectric gate structure 426-4 is between and in contact with the gate end dielectric structure 418-4 and 418-8.

In some embodiments, the dielectric gate structures 426 further extend into the substrate 401 in the Z-direction, as shown in FIG. 5I. In some embodiments, bottom surfaces of the dielectric gate structures 426 are lower than the topmost surfaces of the substrate 401 and the bottom surfaces of the gate end dielectric structures 418, as shown in FIGS. 5F and 5I. Furthermore, each of the dielectric gate structures 426 has a depth D2 that extends into the substrate 401 in a range from about 15 nm to about 150 nm, as shown in FIG. 5I. In other words, a distance between the bottom surfaces of the dielectric gate structures 426 and the topmost surfaces of the substrate 401 is in a range from about 15 nm to about 150 nm, as shown in FIG. 5I.

In some embodiments, the dielectric gate structures 426 includes the dielectric material such as SiO₂, Si₃N₄, SiON, SiOCN, SiOC, SiCN, a metal oxide such as HrO₂, ZrO₂, hafnium aluminum oxide, and hafnium silicate, or other suitable material, and may be formed by CVD, PVD, ALD, or other suitable methods.

As shown in FIGS. 5H and 5I, the SRAM cells 100A and 100A’ further include silicide features 424 over the source/drain features 412N and 412P. The silicide features 424 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

Referring to FIGS. 5A, 5H, and 5I, the SRAM cells 100A and 100A’ further include source/drain contacts 430 (including source/drain contacts 430-1 to 430-15) in an inter-layer dielectric (ILD) layer 428. As shown in FIGS. 5A, 5H, and 5I, the source/drain contacts 430 extend lengthwise in the X-direction. The source/drain contacts 430 are self-aligned source/drain contacts. This means that the source/drain contacts 430 are formed by using the gate spacers 420 as a mask. Therefore, the source/drain contacts 430 are in direct contact with the gate spacers 420, as shown in FIGS. 5H and 5I. In some embodiments, the gate spacers 420 are trimmed due to the gate spacers 420 serving as the mask for forming the source/drain contacts 430. Therefore, the thickness of the gate spacers 420 in the Y-direction is less than the thickness of the inner spacers 422 in the Y-direction, as discussed above.

In the top view, as shown in FIG. 5A, the source/drain contacts 430-1, 430-2, 430-13 lengthwise overlap the cell boundary CB, the source/drain contacts 430-3, 430-14, 430-15 lengthwise overlap the cell boundary CB’, and the source/drain contact 430-8 lengthwise overlap the cell boundaries CB and CB’.

In the top view, the source/drain contact 430-1 is adjacent to the gate structure 404-1 (or is adjacent to the write-port PG transistor WPG1) in the Y-direction; the source/drain contact 430-2 is adjacent to the gate structure 404-5 (or is adjacent to the read-port PG transistor RPG) in the Y-direction; the source/drain contact 430-3 is adjacent to the gate structure 404-7 (or is adjacent to the write-port PG transistor WPG1’) in the Y-direction; the source/drain contact 430-4 is between the gate structures 404-1 and 404-2 (or between the write-port PG transistor WPG1 and the write-port PD transistor WPD1) in the Y-direction; the source/drain contact 430-5 is between the gate structures 404-5 and 404-6 (or between the read-port PG transistor RPG and the read-port PD transistor RPD) in the Y-direction; the source/drain contact 430-6 is between the gate structures 404-7 and 404-8 (or between the write-port PG transistor WPG1’ and the write-port PD transistor WPD1’) in the Y-direction; the source/drain contact 430-7 is between the gate structures 404-2 and 404-3 (or between the write-port PU transistors WPU1 and WPU2) in the Y-direction; the source/drain contact 430-8 is between the gate structures 404-2 and 404-3, between the gate structures 404-2 and 404-9, and between the gate structures 404-8 and 404-9 (or between the write-port PD transistors WPD1 and WPD2, between the read-port PD transistors RPD and RPD’, and between the write-port PD transistors WPD1’ and WPD2’) in the Y-direction; the source/drain contact 430-9 is between the gate structures 404-8 and 404-9 (or between the write-port PU transistors WPU1’ and WPU2’) in the Y-direction; the source/drain contact 430-10 is between the gate structures 404-3 and 404-4 (or between the write-port PG transistor WPG2 and the write-port PD transistor WPD2) in the Y-direction; the source/drain contact 430-11 is between the gate structures 404-11 and 404-12 (or between the read-port PG transistor RPG’ and the read-port PD transistor RPD’) in the Y-direction; the source/drain contact 430-12 is between the gate structures 404-9 and 404-10 (or between the write-port PG transistor WPG2’ and the write-port PD transistor WPD2’) in the Y-direction; the source/drain contact 430-13 is adjacent to the gate structure 404-4 (or is adjacent to the write-port PG transistor WPG2) in the Y-direction; the source/drain contact 430-14 is adjacent to the gate structure 404-11 (or is adjacent to the read-port PG transistor RPG’) in the Y-direction; and the source/drain contact 430-15 is adjacent to the gate structure 404-10 (or is adjacent to the write-port PG transistor WPG2’) in the Y-direction.

Furthermore, each of the source/drain contacts 430 is over and electrically connected to the respective source/drain features 412N/412P. Specifically, as shown in FIGS. 5A, 5H, and 5I, the source/drain contact 430-1 is over and electrically connected to the source/drain feature 412N of the write-port PG transistor WPG1; the source/drain contact 430-2 is over and electrically connected to the source/drain feature 412N of the read-port PG transistor RPG; the source/drain contact 430-3 is over and electrically connected to the source/drain feature 412N of the write-port PG transistor WPG1’; the source/drain contact 430-4 is over and electrically connected to the source/drain feature 412N shared by the write-port PG transistor WPG1 and the write-port PD transistor WPD1 (also referred to as common source/drain or common drain) and the source/drain feature 412P of the write-port PU transistor WPU1, which corresponds to the data node ND shown in FIG. 2; the source/drain contact 430-5 is over and electrically connected to the source/drain feature 412N shared by the read-port PG transistor RPG and the read-port PD transistor RPD; the source/drain contact 430-6 is over and electrically connected to the source/drain feature 412N shared by the write-port PG transistor WPG1’ and the write-port PD transistor WPD1’ (also referred to as common source/drain or common drain) and the source/drain feature 412P of the write-port PU transistor WPU1’, which corresponds to the data node ND shown in FIG. 2; the source/drain contact 430-7 is over and electrically connected to the source/drain feature 412P shared by the write-port PU transistors WPU1 and WPU2; the source/drain contact 430-8 is over and electrically connected to the source/drain feature 412N shared by the write-port PD transistor WPD1 and WPD2, the source/drain feature 412N shared by the read-port PD transistors RPD and RPD’, and the source/drain feature 412N shared by the write-port PD transistor WPD1’ and WPD2’; the source/drain contact 430-9 is over and electrically connected to the source/drain feature 412P shared by the write-port PU transistors WPU1’ and WPU2’; the source/drain contact 430-10 is over and electrically connected to the source/drain feature 412N shared by the write-port PG transistor WPG2 and the write-port PD transistor WPD2 (also referred to as common source/drain or common drain) and the source/drain feature 412P of the write-port PU transistor WPU2, which corresponds to the data node NDB shown in FIG. 2; the source/drain contact 430-11 is over and electrically connected to the source/drain feature 412N shared by the read-port PG transistor RPG’ and the read-port PD transistor RPD’; the source/drain contact 430-12 is over and electrically connected to the source/drain feature 412N shared by the write-port PG transistor WPG2’ and the write-port PD transistor WPD2’ (also referred to as common source/drain or common drain) and the source/drain feature 412P of the write-port PU transistor WPU1’, which corresponds to the data node NDB shown in FIG. 2; the source/drain contact 430-13 is over and electrically connected to the source/drain feature 412N of the write-port PG transistor WPG2; the source/drain contact 430-14 is over and electrically connected to the source/drain feature 412N of the read-port PG transistor RPG’; and the source/drain contact 430-15 is over and electrically connected to the source/drain feature 412N of the write-port PG transistor WPG2’.

Furthermore, the source/drain contact 430-8 is also over and in contact with the gate end dielectric structures 418-1 and 418-2, as shown in FIGS. 5A and 5G. As shown in FIG. 5G, the source/drain contact 430-8 further extends into the gate end dielectric structures 418-1 and 418-2 in the Z-direction. In some embodiments, a bottom surface of the source/drain contact 430-8 is lower than topmost surfaces of the gate end dielectric structures 418-1 and 418-2, as shown in FIG. 5G. Furthermore, the source/drain contact 430-8 has a depth D3 that extends into the gate end dielectric structures 418-1 and 418-2 in a range from about 3 nm to about 50 nm, as shown in FIG. 5G. In other words, a distance between the bottom surface of the source/drain contact 430-8 and the topmost surfaces of the gate end dielectric structures 418-1 and 418-2 is in a range from about 3 nm to about 50 nm, as shown in FIG. 5G.

The source/drain contacts 430 may each include a conductive material such as Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 430 may each include single conductive material layer or multiple conductive layers.

As shown in FIGS. 5A to 5I, the SRAM cells 100A and 100A’ further include an interconnection structure having gate vias 502 (including gate vias 502-1 to 502-10), vias 504 (including vias 504-1 to 504-14), metal conductors 506 (including metal conductors 506-1 to 506-17), vias 508 (including vias 508-1 to 508-10), metal conductors 510 (including metal conductors 510-1 to 510-8), vias 512 (including vias 512-1 to 512-6), metal conductors 514 (including metal conductors 514-1 to 514-6), vias 516 (including vias 516-1 to 516-4), metal conductors 518 (including metal conductors 518-1 to 518-3), and an inter-metal dielectric (IMD) layer 520, which are over the transistors in the SRAM cells 100A and 100A’ (e.g., the write-port PG transistors WPG1, WPG2, WPG1’, and WPG2’, the write-port PD transistors WPD1, WPD2, WPD1’, and WPD2’, the write-port PU transistors WPU1, WPU2, WPU1’, and WPU2’, the read-port PG transistors RPG and RPG’, and the read-port PD transistors RPD and RPD’).

The gate vias 502 and vias 504 are in the ILD layer 428. The vias 508, 512, and 516, and metal conductors 506, 510, 514, and 518 are in the IMD layer 520. The metal conductors 506, 510, 514, and 518 are respectively in the metal layers M1, M2, M3, and M4, as discussed above. Therefore, the metal conductors 510 are over the metal conductors 506, the metal conductors 514 are over the metal conductors 510, and the metal conductors 518 are over the metal conductors 514. As show in FIGS. 5A to 5D, the metal conductors 506 and 514 extend lengthwise in the Y-direction, and the metal conductors 510 and 518 extend lengthwise in the X-direction.

Each of the gate vias 502 is vertically between and electrically connected to the respective gate structure 404 and the respective metal conductor 506. Each of the vias 504 is vertically between and electrically connected to the respective source/drain contact 430 and the respective metal conductor 506. Each of the vias 508 is vertically between and electrically connected to the respective metal conductor 506 and the respective metal conductor 510. Each of the vias 512 is vertically between and electrically connected to the respective metal conductor 510 and the respective metal conductor 514. Each of the vias 516 is vertically between and electrically connected to the respective metal conductor 514 and the respective metal conductor 518.

As discussed in FIG. 2, the gate of the read-port PD transistor RPD is coupled with the data node NDB and the gates of the write-port PU transistor WPU1 and the write-port PD transistor WPD1, or the gate of the read-port PD transistor RPD is coupled with the data node ND and the gates of the write-port PU transistor WPU2 and the write-port PD transistor WPD2. However, as shown in FIG. 5A, the gate structure 404-6 of the read-port PD transistor RPD is separated from the gate structure 404-2 of the write-port PU transistor WPU1 and the write-port PD transistor WPD1, and the gate structure 404-12 of the read-port PD transistor RPD’ is separated from the gate structure 404-9 of the write-port PU transistor WPU2’ and the write-port PD transistor WPD2’. Therefore, the gate vias 502-4 and 502-7 are formed with a rectangular shape for respectively connecting the gate structures 404-6 and 404-12 to the gate structures 404-2 and 404-9.

More specifically, the gate via 502-4 is over and in contact with the gate end dielectric structure 418-1 and the gate structures 404-2 and 404-6, and the gate via 502-7 is over and in contact with the gate end dielectric structure 418-2 and the gate structures 404-9 and 404-12, as shown in FIGS. 5A, 5E, and 5G. As such, the gate via 502-4 is electrically connected to the gate structures 404-2 and 404-6, and the gate via 502-7 is electrically connected to the gate structures 404-9 and 404-12. Therefore, the gate structure 404-6 is electrically connected to the gate structure 404-2, and the gate structure 404-12 is electrically connected to the gate structure 404-9. The gate vias 502-4 and 502-7 may extend in the X-direction and also be referred to as rectangular via, as shown in FIG. 5A. In some embodiments, the other gate vias 502, the vias 504, 508, 512, and 516 may have a square shape in the top view. In other embodiments, the other gate vias 502, the vias 504, 508, 512, and 516 may have a circular shape in the top view.

As discussed above, connections of the SRAM cells 100A and 100A’ correspond to the circuit of the SRAM cell 100 shown in FIG. 2. In some embodiments, the metal conductor 506-9 serves as the read bit-line RBL discussed above that shared by the SRAM cells 100A and 100A’. More specifically, the metal conductor 506-9 serving as the read bit-line RBL is shared by the read-port PG transistors RPG and RPG’.

As shown in FIG. 5A, the metal conductor 506-9 is over the read-port PG transistors RPG and RPG’ and the read-port PD transistors RPD and RPD’. In some embodiments, the metal conductor 506-9 overlaps the active are 402-3 in the Y-direction and in the top view. The metal conductor 506-9 is electrically connected to the source/drain feature 412N of the read-port PG transistor RPG through the via 504-7 and the source/drain contact 430-2 and electrically connected to the source/drain feature 412N of the read-port PG transistor RPG’ through the via 504-14 and the source/drain contact 430-14. As shown in FIG. 5A, in the top view, the via 504-7 overlaps the cell boundary CB, and the via 504-14 overlaps the cell boundary CB’. In some embodiments, the metal conductor 506-9 may be referred to as read bit-line conductor.

In some embodiments, the metal conductors 506-1 and 506-17 serves as VDD lines that are electrically coupled to a voltage source (not shown) (e.g., the supply voltage VDD discussed above) and electrically connected to the source/drain features of the write-port PU transistors in the SRAM cells 100A and 100A’.

As shown in FIG. 5A, for the SRAM cell 100A, the metal conductor 506-1 is electrically connected to the source/drain feature 412P shared by the write-port PU transistors WPU1 and WPU2 through the via 504-1 and the source/drain contact 430-7.

For the SRAM cell 100A’, the metal conductor 506-17 is electrically connected to the source/drain feature 412P shared by the write-port PU transistors WPU1’ and WPU2’ through the via 504-8 and the source/drain contact 430-9.

As shown in FIGS. 5A and 5B, in the top view, the via 504-1 overlaps the cell boundary CB, and the via 504-8 overlaps the cell boundary CB’. Furthermore, in the top view, the metal conductor 506-1 lengthwise overlaps the cell boundary CB and the metal conductor 506-17 lengthwise overlaps the cell boundary CB’. In some embodiments, the metal conductors 506-1 and 506-17 may be referred to as the VDD conductors or the VDD lines.

In some embodiments, the metal conductors 506-2 and 506-12 serve as data node ND as discussed above, and the metal conductors 506-6 and 506-16 serve as data node NDB as discussed above. In the top view, as shown in FIG. 5A, the metal conductor 506-2 is across the gate structures 404-2 and 404-3 and the source/drain contact 430-4; the metal conductor 506-6 is across the gate structures 404-2 and 404-3 and the source/drain contact 430-10; the metal conductor 506-12 is across the gate structures 404-8 and 404-9 and the source/drain contact 430-6; and the metal conductor 506-16 is across the gate structures 404-8 and 404-9 and the source/drain contact 430-12.

As shown in FIG. 5A, for the SRAM cell 100A, the metal conductor 506-2 is electrically connected to the source/drain contact 430-4 (thus also electrically connected to the source/drain feature 412N shared by the write-port PG transistor WPG1 and the write-port PD transistor WPD1 and the source/drain feature 412P of the write-port PU transistor WPU1) through the via 504-2 and the gate structure 404-3 through the gate via 502-1; the metal conductor 506-6 is electrically connected to the source/drain contact 430-10 (thus also electrically connected to the source/drain feature 412N shared by the write-port PG transistor WPG2 and the write-port PD transistor WPD2 and the source/drain feature 412P of the write-port PU transistor WPU2) through the via 504-5 and the gate structures 404-2 and 404-6 through the gate via 502-4.

For the SRAM cell 100A’, the metal conductor 506-12 is electrically connected to the source/drain contact 430-6 (thus also electrically connected to the source/drain feature 412N shared by the write-port PG transistor WPG1’ and the write-port PD transistor WPD1’ and the source/drain feature 412P of the write-port PU transistor WPU1’) through the via 504-12 and the gate structures 404-9 and 404-12 through the gate via 502-7; the metal conductor 506-16 is electrically connected to the source/drain contact 430-12 (thus also electrically connected to the source/drain feature 412N shared by the write-port PG transistor WPG2’ and the write-port PD transistor WPD2’ and the source/drain feature 412P of the write-port PU transistor WPU2’) through the via 504-9 and the gate structure 404-8 through the gate via 502-10.

Since the metal conductor 506-2 is connected to the source/drain contact 430-4 that corresponds to the data node ND, the metal conductor 506-12 is connected to the source/drain contact 430-6 that corresponds to the data node ND, the metal conductor 506-6 is connected to the source/drain contact 430-10 that corresponds to the data node NDB, and the metal conductor 506-16 is connected to the source/drain contact 430-12 that corresponds to the data node NDB, the metal conductors 506-2, 506-12, 506-6, and 506-16 may also be referred to as data node lines or data node conductors.

In some embodiments, the metal conductors 510-2 and 510-7 respectively serve as the write word-lines WWL discussed above that controls and electrically connected to the gate structures (more specifically, the gate electrodes) of the write-port PG transistors. More specifically, the metal conductor 510-2 and 510-7 respectively serve as the write word-lines WWL for the SRAM cells 100A and 100A’.

As shown in FIGS. 5A and 5B, for the SRAM cell 100A, the metal conductor 510-2 is electrically connected to the gate structure 404-1 of the write-port PG transistor WPG1 through the via 508-1, the metal conductor 506-3, and the gate via 502-2, and is electrically connected to the gate structure 404-4 of the write-port PG transistor WPG2 through the via 508-1, the metal conductor 506-3, and the gate via 502-3.

For the SRAM cell 100A’, the metal conductor 510-7 is electrically connected to the gate structure 404-7 of the write-port PG transistor WPG1’ through the via 508-10, the metal conductor 506-15, and the gate via 502-8, and is electrically connected to the gate structure 404-10 of the write-port PG transistor WPG2’ through the via 508-10, the metal conductor 506-15, and the gate via 502-9.

In some embodiments, the metal conductors 510-2 and 510-7 may be referred to as write word-line conductors. In some embodiments, the metal conductors 506-3 and 506-15 may be referred to as write word-line landing pads.

In some embodiments, the metal conductors 514-2 and 514-5 respectively serve as the write bit-line WBL and the write bit-line-bar WBLB discussed above that shared by the SRAM cells 100A and 100A’. More specifically, the metal conductor 514-2 serving as the write bit-line WBL is shared by the write-port PG transistors WPG1 and WPG1’, and the metal conductor 514-5 serving as the write bit-line-bar WBLB is shared by the write-port PG transistors WPG2 and WPG2’.

As shown in FIGS. 5A to 5C, for the SRAM cells 100A and 100A’, the metal conductor 514-2 is electrically connected to the source/drain feature 412N of the write-port PG transistor WPG1 through the via 512-2, the metal conductor 510-1, the via 508-3, the metal conductor 506-5, the via 504-4, and the source/drain contact 430-1, and is electrically connected to the source/drain feature 412N of the write-port PG transistor WPG1’ through the via 512-2, the metal conductor 510-1, the via 508-7, the metal conductor 506-11, the via 504-11, and the source/drain contact 430-3; and the metal conductor 514-5 is electrically connected to the source/drain feature 412N of the write-port PG transistor WPG2 through the via 512-5, the metal conductor 510-8, the via 508-4, the metal conductor 506-7, the via 504-6, and the source/drain contact 430-13, and is electrically connected to the source/drain feature 412N of the write-port PG transistor WPG2’ through the via 512-5, the metal conductor 510-8, the via 508-8, the metal conductor 506-13, the via 504-13, and the source/drain contact 430-15.

As shown in FIGS. 5A to 5C, in the top view, the vias 512-2, 508-3, 508-4, 504-4, 504-6 overlap the cell boundary CB, and the vias 512-5, 508-7, 508-8, 504-11, 504-13 overlap the cell boundary CB’. Furthermore, in the top view, the metal conductors 510-1 and 510-8 lengthwise overlap the cell boundaries CB and CB’. In some embodiments, the metal conductor 514-2 may be referred to as write bit-line conductors, and the metal conductor 514-5 may be referred to as write bit-line-bar conductors. In some embodiments, the metal conductors 510-1, 506-5, and 506-11 may be referred to as write bit-line landing pads, and the metal conductors 510-8, 506-7, and 506-13 may be referred to as write bit-line-bar landing pads.

In some embodiments, the metal conductors 518-1 and 518-3 respectively serve as the read word-lines RWL discussed above that controls and electrically connected to the gate structures (more specifically, the gate electrodes) of the read-port PG transistors. More specifically, the metal conductor 518-1 and 518-3 respectively serve as the read word-lines RWL for the SRAM cells 100A and 100A’.

As shown in FIGS. 5A to 5D, for the SRAM cell 100A, the metal conductor 518-1 is electrically connected to the gate structure 404-5 of the read-port PG transistor RPG through the via 516-3, the metal conductor 514-4, the via 512-4, the metal conductor 510-5, the via 508-6, the metal conductor 506-10, and the gate via 502-6.

For the SRAM cell 100A’, the metal conductor 518-3 is electrically connected to the gate structure 404-11 of the read-port PG transistor RPG’ through the via 516-2, the metal conductor 514-3, the via 512-3, the metal conductor 510-4, the via 508-5, the metal conductor 506-8, and the gate via 502-5.

In some embodiments, the metal conductors 518-1 and 518-3 may be referred to as read word-line conductor. In some embodiments, the metal conductors 514-3, 514-4, 510-4, 510-5, 506-8, and 506-10 may be referred to as read word-line landing pads.

The metal conductors 514-1, 514-6, and 518-2 serve as VSS lines that are coupled together, electrically coupled to a voltage source (not shown) (e.g., the reference voltage VSS discussed above), and electrically connected to the source/drain features of the write-port PD transistors and the read-port PD transistors in the SRAM cells 100A and 100A’.

As shown in FIGS. 5A to 5C, the metal conductors 514-1 and 514-6 are electrically connected to the source/drain feature 412N shared by the write-port PD transistor WPD1 and WPD2, the source/drain feature 412N shared by the read-port PD transistors RPD and RPD’, and the source/drain feature 412N shared by the write-port PD transistor WPD1’ and WPD2’ through the vias 512-1 and 512-6, the metal conductors 510-3 and 510-6, the vias 508-2 and 508-9, the metal conductors 506-4 and 506-14, the vias 504-3 and 504-10, and the source/drain contact 430-8. As shown in FIG. 5D, the metal conductor 518-2 is electrically connected to the metal conductor 514-1 through the via 516-1 and is electrically connected to the metal conductor 514-6 through the via 516-4. In some embodiments, the metal conductors 510-3, 510-6, 506-4, 506-14 serve as and be referred to as VSS local connections. As such, the metal conductors 506-4, 506-14, 510-3, 510-6, 514-1, 514-6, and 518-2 and vias 504-3, 504-10, 508-2, 508-9, 512-1, 512-6, 516-1, and 516-4 may construct a power mesh to supply the reference voltage VSS to the write-port PD transistors and the read-port PD transistors.

As shown in FIGS. 5A to 5D, in the top view, the via 512-1 and 516-1 overlap the cell boundary CB, and the vias 512-6 and 516-4 overlap the cell boundary CB’. Furthermore, in the top view, the metal conductor 514-1 lengthwise overlaps the cell boundary CB, the metal conductor 514-6 lengthwise overlaps the cell boundary CB’, and the metal conductor 518-2 lengthwise overlap the cell boundaries CB and CB’. In some embodiments, the metal conductors 514-1, 514-6, and 518-2 may be referred to as VSS conductors or VSS lines.

The ILD layer 428 and the IMD layer 520 each may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the gate vias 502, the vias 504, the metal conductors 506, the vias 508, the metal conductors 510, the vias 512, the metal conductors 514, the vias 516, and the metal conductors 518 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

As shown in FIGS. 5A to 5D, the metal conductors 510-2 and 510-7 serving as the write word-lines WWL and the metal conductors 518-1 and 518-3 serving as the read word-lines RWL are more concerned about the resistance, so that the metal conductors 510-2, 510-7, 518-1, and 518-3may be disposed at the higher metal layer to have more space, thereby it may be designed with wider width to reduce the resistance. In some embodiments, the metal conductors 510-2, 510-7, 518-1, and 518-3 may have the widest width than other metal conductors, as shown in FIGS. 5A to 5D. Furthermore, metal conductors 514-2 and 514-5 respectively serving as the write bit-line WBL and the write bit-line-bar WBLB may also be designed with wider width, so that reducing the circuit resistance. In addition, the metal conductor 506-9 serving as the read bit-line RBL is more concerned about the capacitance, so that the metal conductors 506-6 and 506-7 are preferred to put in lowest level metallization layer (e.g., the metal layer M1 discussed above) for bit-line capacitance reduction. This is also means that the crowded space at the interconnection structure in existing technologies are relieved to reduce the routing complexity of the SRAM cells.

Generally, the SRAM cells in the same column share the same write bit-line WBL and the same write bit-line-bar WBLB. Although the SRAM cells 100A and 100A’ in the adjacent two rows and in the same column are abutted with each other in the X-direction, the SRAM cells 100A and 100A’ still share the metal conductor 514-2 serving as the write bit-line WBL and the metal conductor 514-5 serving as the write bit-line-bar WBLB, as discussed above. As such, the routing design of the metal conductor 514-2 serving as the write bit-line WBL and the metal conductor 514-5 serving as the write bit-line-bar WBLB do not increase the routing complexity for the abutted SRAM cells 100A and 100A’.

It should be noted that shapes of the SRAM cells 100A and 100A’ are 180 degree rotation symmetry (specifically, the cell boundaries CB and CB’). However, for convenience to route the metal conductor 514-2 serving as the write bit-line WBL and the metal conductor 514-5 serving as the write bit-line-bar WBLB shared by the SRAM cells 100A and 100A’. The transistors in the SRAM cells 100A and 100A’ are non- rotation symmetry. As shown in FIG. 5A, the write-port PG transistors WPG1 and WPG1’ are arranged and aligned in the X-direction, and the write-port PG transistors WPG2 and WPG2’ are arranged and aligned in the X-direction. Furthermore, the source/drain contacts 430-4 and 430-6 which corresponds to the data node ND are arranged and aligned in the X-direction, and the source/drain contacts 430-10 and 430-12 which corresponds to the data node NDB are arranged and aligned in the X-direction.

FIGS. 6A to 6F illustrate top views (or layouts) of two adjacent SRAM cells 100A and 100A’ in a portion of a array 1000 that can be one embodiment of the SRAM cells 100 in adjacent two rows implemented in the memory region 20, in accordance with some embodiments of the present disclosure. FIG. 6A illustrates the features in the device region (including transistors), the metal conductors in the first metal layer (M1), and vias (V0) vertically between the features and the first metal layer (M1). FIG. 6B illustrates the metal conductors in the first metal layer (M1) and the second metal layer (M2), and vias (V1) vertically between the first metal layer (M1) and the second metal layer (M2). FIG. 6C illustrates the metal conductors in the second metal layer (M2) and the third metal layer (M3), and vias (V2) vertically between the second metal layer (M2) and the third metal layer (M3). FIG. 6D illustrates the metal conductors in the third metal layer (M3) and the fourth metal layer (M4), and vias (V3) vertically between the third metal layer (M3) and the fourth metal layer (M4). FIG. 6E illustrates the metal conductors in the fourth metal layer (M4) and the fifth metal layer (M5), and vias (V4) vertically between the fourth metal layer (M4) and the fifth metal layer (M5). FIG. 6F illustrates the metal conductors in the fifth metal layer (M5) and the sixth metal layer (M6), and vias (V5) vertically between the fifth metal layer (M5) and the sixth metal layer (M6).

FIG. 6G is an X-Z cross-sectional view of the array 1000 along a line F-F’ in FIG. 6A, in accordance with some embodiments of the present disclosure. FIG. 6H is an X-Z cross-sectional view of the array 1000 along a line G-G’ in FIG. 6A, in accordance with some embodiments of the present disclosure. The SRAM cells 100A and 100A’ shown in FIGS. 6A to 6H are similar to the SRAM cells 100A and 100A’ shown in FIGS. 5A to 5I, except that the SRAM cells 100A and 100A’ shown in FIGS. 6A to 6H have an interconnection structure different than that shown in FIGS. 5A to 5I.

Furthermore, as discussed above, the gate end dielectric structures 418-5 to 418-8 are optional and the dielectric gate structures 426-1, 426-2, 426-3, and 426-4 are respectively aligned and in contact with the gate structures 404-1, 404-4, 404-7, and 404-10 in the X-direction, as shown in FIGS. 6A and 6H.

As shown in FIGS. 6A to 6H, the SRAM cells 100A and 100A’ further include an interconnection structure having gate vias 602 (including gate vias 602-1 to 602-12), vias 604 (including vias 604-1 to 604-14), metal conductors 606 (including metal conductors 606-1 to 606-19), vias 608 (including vias 608-1 to 608-14), metal conductors 610 (including metal conductors 610-1 to 610-9), vias 612 (including vias 612-1 to 612-8), metal conductors 614 (including metal conductors 614-1 to 614-8), vias 616 (including vias 616-1 to 616-6), metal conductors 618 (including metal conductors 618-1 to 618-6), vias 620 (including vias 620-1 to 620-4), metal conductors 622 (including metal conductors 622-1 to 622-4), vias 624 (including vias 624-1 and 624-2), the metal conductors 626 (including metal conductors 626-1 and 626-2), and an inter-metal dielectric (IMD) layer 628, which are over the transistors in the SRAM cells 100A and 100A’ (e.g., the write-port PG transistors WPG1, WPG2, WPG1’, and WPG2’, the write-port PD transistors WPD1, WPD2, WPD1’, and WPD2’, the write-port PU transistors WPU1, WPU2, WPU1’, and WPU2’, the read-port PG transistors RPG and RPG’, and the read-port PD transistors RPD and RPD’).

The gate vias 602 and vias 604 are in the ILD layer 428. The vias 608, 612, 616, 620, and 624, and metal conductors 606, 610, 614, 618, 622, and 626 are in the IMD layer 628. The metal conductors 606, 610, 614, 618, 622, and 626 are respectively in the metal layers M1, M2, M3, M4, M5, and M6, as discussed above. Therefore, the metal conductors 610 are over the metal conductors 606, the metal conductors 614 are over the metal conductors 610, the metal conductors 618 are over the metal conductors 614, the metal conductors 622 are over the metal conductors 618, and the metal conductors 626 are over the metal conductors 622. As show in FIGS. 6A to 6F, the metal conductors 606, 614, and 622 extend lengthwise in the Y-direction, and the metal conductors 610, 618, and 626 extend lengthwise in the X-direction.

Each of the gate vias 602 is vertically between and electrically connected to the respective gate structure 404 and the respective metal conductor 606. Each of the vias 604 is vertically between and electrically connected to the respective source/drain contact 430 and the respective metal conductor 606. Each of the vias 608 is vertically between and electrically connected to the respective metal conductor 606 and the respective metal conductor 610. Each of the vias 612 is vertically between and electrically connected to the respective metal conductor 610 and the respective metal conductor 614. Each of the vias 616 is vertically between and electrically connected to the respective metal conductor 614 and the respective metal conductor 618. Each of the vias 620 is vertically between and electrically connected to the respective metal conductor 618 and the respective metal conductor 622. Each of the vias 624 is vertically between and electrically connected to the respective metal conductor 622 and the respective metal conductor 626.

As discussed in FIG. 2, the gate of the read-port PD transistor RPD is coupled with the data node NDB and the gates of the write-port PU transistor WPU1 and the write-port PD transistor WPD1. However, as shown in FIG. 5A, the gate structure 404-6 of the read-port PD transistor RPD is separated from the gate structure 404-2 of the write-port PU transistor WPU1 and the write-port PD transistor WPD1, and the gate structure 404-12 of the read-port PD transistor RPD’ is separated from the gate structure 404-9 of the write-port PU transistor WPU2’ and the write-port PD transistor WPD2’.

Therefore, in the SRAM cell 100A, the gate vias 602-4 and 602-5, the metal conductors 606-4 and 606-8, the vias 608-2 and 608-6, and the metal conductor 610-2 are formed for connecting the gate structure 404-6 to the gate structure 404-2, as shown in FIGS. 6A and 6B. In the SRAM cell 100A’, the gate vias 602-8 and 602-9, the metal conductors 606-12 and 606-16, the vias 608-9 and 608-13, and the metal conductor 610-8 are formed for connecting the gate structure 404-12 to the gate structure 404-8, as shown in FIGS. 6A and 6B.

More specifically, in the SRAM cell 100A, the gate vias 602-4 and 602-5 are respectively over and electrically connected to the gate structures 404-2 and 404-6. The metal conductor 610-2 is over and electrically connected to the gate via 602-4 through the via 608-2 and the metal conductor 606-4, and over and electrically connected to the gate via 602-5 through the via 608-6 and the metal conductor 606-8. As such, the gate structure 404-6 is electrically connected to the gate structure 404.

In the SRAM cell 100A’, the gate vias 602-8 and 602-9 are respectively over and electrically connected to the gate structures 404-12 and 404-8. The metal conductor 610-8 is over and electrically connected to the gate vias 602-8 through the via 608-9 and the metal conductor 606-12, and over and electrically connected to the gate vias 602-9 through the via 608-13 and the metal conductor 606-16. As such, the gate structure 404-12 is electrically connected to the gate structure 404-8.

In some embodiments, the gate vias 502, the vias 504, 508, 512, and 516 may have a square shape in the top view. In other embodiments, the gate vias 502, the vias 504, 508, 512, and 516 may have a circular shape in the top view.

As discussed above, connections of the SRAM cells 100A and 100A’ correspond to the circuit of the SRAM cell 100 shown in FIG. 2. In some embodiments, the metal conductor 606-10 serves as the read bit-line RBL discussed above that shared by the SRAM cells 100A and 100A’. More specifically, the metal conductor 606-10 serving as the read bit-line RBL is shared by the read-port PG transistors RPG and RPG’.

As shown in FIG. 6A, the metal conductor 606-10 is over the read-port PG transistors RPG and RPG’ and the read-port PD transistors RPD and RPD’. In some embodiments, the metal conductor 606-10 overlaps the active are 402-3 in the Y-direction and in the top view. The metal conductor 606-10 is electrically connected to the source/drain feature 412N of the read-port PG transistor RPG through the via 604-7 and the source/drain contact 430-2 and electrically connected to the source/drain feature 412N of the read-port PG transistor RPG’ through the via 604-8 and the source/drain contact 430-14. As shown in FIG. 5A, in the top view, the via 604-7 overlaps the cell boundary CB, and the via 604-8 overlaps the cell boundary CB’. In some embodiments, the metal conductor 606-10 may be referred to as read bit-line conductor.

In some embodiments, the metal conductors 606-1 and 606-19 serves as VDD lines that are electrically coupled to a voltage source (not shown) (e.g., the supply voltage VDD discussed above) and electrically connected to the source/drain features of the write-port PU transistors in the SRAM cells 100A and 100A’.

As shown in FIG. 6A, for the SRAM cell 100A, the metal conductor 606-1 is electrically connected to the source/drain feature 412P shared by the write-port PU transistors WPU1 and WPU2 through the via 604-1 and the source/drain contact 430-7.

For the SRAM cell 100A’, the metal conductor 606-19 is electrically connected to the source/drain feature 412P shared by the write-port PU transistors WPU1’ and WPU2’ through the via 604-14 and the source/drain contact 430-9.

As shown in FIGS. 6A and 6B, in the top view, the via 604-1 overlaps the cell boundary CB, and the via 604-14 overlaps the cell boundary CB’. Furthermore, in the top view, the metal conductor 606-1 lengthwise overlaps the cell boundary CB and the metal conductor 606-19 lengthwise overlaps the cell boundary CB’. In some embodiments, the metal conductors 606-1 and 606-19 may be referred to as the VDD conductors or the VDD lines.

In some embodiments, the metal conductors 606-2 and 606-18 serve as data node ND as discussed above, and the metal conductors 606-4 and 606-16 serve as data node NDB as discussed above. In the top view, as shown in FIG. 6A, the metal conductor 606-2 is across the gate structures 404-2 and 404-3 and the source/drain contact 430-4; the metal conductor 606-4 is across the gate structures 404-2 and 404-3 and the source/drain contact 430-10; the metal conductor 606-18 is across the gate structures 404-8 and 404-9 and the source/drain contact 430-6; and the metal conductor 606-16 is across the gate structures 404-8 and 404-9 and the source/drain contact 430-12.

As shown in FIG. 6A, for the SRAM cell 100A, the metal conductor 606-2 is electrically connected to the source/drain contact 430-4 (thus also electrically connected to the source/drain feature 412N shared by the write-port PG transistor WPG1 and the write-port PD transistor WPD1 and the source/drain feature 412P of the write-port PU transistor WPU1) through the via 604-2 and the gate structure 404-3 through the gate via 602-1; the metal conductor 606-4 is electrically connected to the source/drain contact 430-10 (thus also electrically connected to the source/drain feature 412N shared by the write-port PG transistor WPG2 and the write-port PD transistor WPD2 and the source/drain feature 412P of the write-port PU transistor WPU2) through the via 604-3, the gate structure 404-2 through the gate via 602-4, and the gate structure 404-6 through the via 608-2 ,the meatal conductior 610-2, the via 608-6, the metal conductor 606-8, and the gate via 602-5.

For the SRAM cell 100A’, the metal conductor 606-18 is electrically connected to the source/drain contact 430-6 (thus also electrically connected to the source/drain feature 412N shared by the write-port PG transistor WPG1’ and the write-port PD transistor WPD1’ and the source/drain feature 412P of the write-port PU transistor WPU1’) through the via 604-13 and the gate structure 404-9 through the gate via 602-12; the metal conductor 606-16 is electrically connected to the source/drain contact 430-12 (thus also electrically connected to the source/drain feature 412N shared by the write-port PG transistor WPG2’ and the write-port PD transistor WPD2’ and the source/drain feature 412P of the write-port PU transistor WPU2’) through the via 604-12, the gate structure 404-8 through the gate via 602-9, and the gate structure 404-12 through the via 608-13 ,the meatal conductior 610-8, the via 608-9, the metal conductor 606-12, and the gate via 602-8.

Since the metal conductor 606-2 is connected to the source/drain contact 430-4 that corresponds to the data node ND, the metal conductor 606-18 is connected to the source/drain contact 430-6 that corresponds to the data node ND, the metal conductor 606-4 is connected to the source/drain contact 430-10 that corresponds to the data node NDB, and the metal conductor 606-16 is connected to the source/drain contact 430-12 that corresponds to the data node NDB, the metal conductors 606-2, 606-18, 606-4, and 606-16 may also be referred to as data node lines or data node conductors.

In some embodiments, the metal conductors 618-1 and 618-6 respectively serve as the write word-lines WWL discussed above that controls and electrically connected to the gate structures (more specifically, the gate electrodes) of the write-port PG transistors. More specifically, the metal conductor 618-1 and 618-6 respectively serve as the write word-lines WWL for the SRAM cells 100A and 100A’.

As shown in FIGS. 6A to 6D, for the SRAM cell 100A, the metal conductor 618-6 is electrically connected to the gate structure 404-1 of the write-port PG transistor WPG1 through the via 616-2, the metal conductor 614-2, the via 612-2, the metal conductor 610-6, the via 608-1, the metal conductor 606-3, and the gate via 602-2, and is electrically connected to the gate structure 404-4 of the write-port PG transistor WPG2 through the via 616-2, the metal conductor 614-2, the via 612-2, the metal conductor 610-6, the via 608-1, the metal conductor 606-3, and the gate via 602-3.

For the SRAM cell 100A’, the metal conductor 618-1 is electrically connected to the gate structure 404-7 of the write-port PG transistor WPG1’ through the via 616-5, the metal conductor 614-7, the via 612-7, the metal conductor 610-4, the via 608-14, the metal conductor 606-17, and the gate via 602-10, and is electrically connected to the gate structure 404-10 of the write-port PG transistor WPG2’ through the via 616-5, the metal conductor 614-7, the via 612-7, the metal conductor 610-4, the via 608-14, the metal conductor 606-17, and the gate via 602-11.

In some embodiments, the metal conductors 618-1 and 618-6 may be referred to as write word-line conductors. In some embodiments, the metal conductors 614-2, 614-7, 610-4, 610-6, 606-3, and 606-17 may be referred to as write word-line landing pads.

In some embodiments, the metal conductors 614-3 and 614-6 respectively serve as the write bit-line WBL and the write bit-line-bar WBLB discussed above that shared by the SRAM cells 100A and 100A’. More specifically, the metal conductor 614-3 serving as the write bit-line WBL is shared by the write-port PG transistors WPG1 and WPG1’, and the metal conductor 614-6 serving as the write bit-line-bar WBLB is shared by the write-port PG transistors WPG2 and WPG2’.

As shown in FIGS. 6A to 6C, for the SRAM cells 100A and 100A’, the metal conductor 614-3 is electrically connected to the source/drain feature 412N of the write-port PG transistor WPG1 through the via 612-3, the metal conductor 610-1, the via 608-3, the metal conductor 606-5, the via 604-4, and the source/drain contact 430-1, and is electrically connected to the source/drain feature 412N of the write-port PG transistor WPG1’ through the via 612-3, the metal conductor 610-1, the via 608-10, the metal conductor 606-13, the via 604-9, and the source/drain contact 430-3; and the metal conductor 614-6 is electrically connected to the source/drain feature 412N of the write-port PG transistor WPG2 through the via 612-6, the metal conductor 610-9, the via 608-5, the metal conductor 606-7, the via 604-6, and the source/drain contact 430-13, and is electrically connected to the source/drain feature 412N of the write-port PG transistor WPG2’ through the via 612-6, the metal conductor 610-9, the via 608-12, the metal conductor 606-15, the via 604-11, and the source/drain contact 430-15.

As shown in FIGS. 6A to 6C, in the top view, the vias 612-3, 608-3, 608-5, 604-4, 604-6 overlap the cell boundary CB, and the vias 612-6, 608-10, 608-12, 604-9, 604-11 overlap the cell boundary CB’. Furthermore, in the top view, the metal conductors 610-1 and 610-9 lengthwise overlap the cell boundaries CB and CB’. In some embodiments, the metal conductor 614-3 may be referred to as write bit-line conductors, and the metal conductor 614-6 may be referred to as write bit-line-bar conductors. In some embodiments, the metal conductors 610-1, 606-5, and 606-13 may be referred to as write bit-line landing pads, and the metal conductors 610-9, 606-7, and 606-15 may be referred to as write bit-line-bar landing pads.

In some embodiments, the metal conductors 626-1 and 626-6 respectively serve as the read word-lines RWL discussed above that controls and electrically connected to the gate structures (more specifically, the gate electrodes) of the read-port PG transistors. More specifically, the metal conductor 626-1 and 626-6 respectively serve as the read word-lines RWL for the SRAM cells 100A and 100A’.

As shown in FIGS. 6A to 6F, for the SRAM cell 100A, the metal conductor 626-1 is electrically connected to the gate structure 404-5 of the read-port PG transistor RPG through the via 624-2, the metal conductor 622-3, the via 620-3, the metal conductor 618-4, the via 616-4, the metal conductor 614-5, the via 612-5, the metal conductor 610-3, the via 608-8, the metal conductor 606-11, and the gate via 602-7.

For the SRAM cell 100A’, the metal conductor 626-6 is electrically connected to the gate structure 404-11 of the read-port PG transistor RPG’ through the via 624-1, the metal conductor 622-2, the via 620-2, the metal conductor 618-3, the via 616-3, the metal conductor 614-4, the via 612-4, the metal conductor 610-7, the via 608-7, the metal conductor 606-9, and the gate via 602-6.

In some embodiments, the metal conductors 626-1 and 626-6 may be referred to as read word-line conductor. In some embodiments, the metal conductors 622-2, 622-3, 618-3, 618-4, 614-4, 614-5, 610-3, 610-7, 606-9, and 606-11 may be referred to as read word-line landing pads.

The metal conductors 610-5, 614-1, 614-8, 622-1, and 622-4 serve as VSS lines that are coupled together, electrically coupled to a voltage source (not shown) (e.g., the reference voltage VSS discussed above), and electrically connected to the source/drain features of the write-port PD transistors and the read-port PD transistors in the SRAM cells 100A and 100A’.

As shown in FIGS. 6A and 6B, the metal conductor 610-5 is electrically connected to the source/drain feature 412N shared by the write-port PD transistor WPD1 and WPD2, the source/drain feature 412N shared by the read-port PD transistors RPD and RPD’, and the source/drain feature 412N shared by the write-port PD transistor WPD1’ and WPD2’ through the vias 608-4 and 608-11, the metal conductors 606-6 and 606-14, the vias 604-5 and 604-10, and the source/drain contact 430-8. As shown in FIGS. 6A to 6C, the metal conductor 614-1 is electrically connected to the metal conductor 610-5 through the via 612-1 and the metal conductor 614-8 is electrically connected to the metal conductor 610-5 through the via 612-8. As shown in FIGS. 6D and 6E, the metal conductor 622-1 is electrically connected to the metal conductor 614-1 through the via 620-1, the metal conductor 618-2, and the via 616-1, and the metal conductor 622-4 is electrically connected to the metal conductor 614-8 through the via 620-4, the metal conductor 618-5, and the via 616-6. In some embodiments, the metal conductors 618-2, 618-5, 606-6, 606-14 serve as and be referred to as VSS local connections. As such, the metal conductors 606-6, 606-14, 610-5, 614-1, 614-8, 618-2, 618-5, 622-1, and 622-4 and vias 604-5, 604-10, 608-4, 608-11, 612-1, 612-8, 616-1, 616-6, 620-1, and 620-4 may construct a power mesh to supply the reference voltage VSS to the write-port PD transistors and the read-port PD transistors.

As shown in FIGS. 6A to 6E, in the top view, the via 612-1, 616-1, and 620-1 overlap the cell boundary CB, and the vias 612-8, 616-6, and 620-4 overlap the cell boundary CB’. Furthermore, in the top view, the metal conductors 614-1 and 622-1 lengthwise overlap the cell boundary CB, the metal conductors 614-8 and 622-4 lengthwise overlap the cell boundary CB’, and the metal conductor 610-5 lengthwise overlap the cell boundaries CB and CB’. In some embodiments, the metal conductors 610-5, 614-1, 614-8, 622-1, and 622-4 may be referred to as VSS conductors or VSS lines.

The IMD 628 may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the gate vias 602, the vias 604, the metal conductors 606, the vias 608, the metal conductors 610, the vias 612, the metal conductors 614, the vias 616, the metal conductors 618, the vias 620, the metal conductors 622, the vias 624, and the metal conductors 626 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

It should be noted that shapes of the SRAM cells 100A and 100A’ are 180 degree rotation symmetry (specifically, the cell boundaries CB and CB’). However, for convenience to route the metal conductor 514-2 serving as the write bit-line WBL and the metal conductor 514-5 serving as the write bit-line-bar WBLB shared by the SRAM cells 100A and 100A’. The transistors in the SRAM cells 100A and 100A’ are non- rotation symmetry. As shown in FIG. 5A, the write-port PG transistors WPG1 and WPG1’ are arranged and aligned in the X-direction, and the write-port PG transistors WPG2 and WPG2’ are arranged and aligned in the X-direction. Furthermore, the source/drain contacts 430-4 and 430-6 which corresponds to the data node ND are arranged and aligned in the X-direction, and the source/drain contacts 430-10 and 430-12 which corresponds to the data node NDB are arranged and aligned in the X-direction.

The embodiments disclosed herein relate to semiconductor devices, and more particularly to semiconductor devices including a metal conductor for the read bit-line that is shared by two SRAM cells in adjacent two rows of an SRAM array, in which the metal conductor is in the lowest metal layer, that can improve cell performance of the SRAM cells. Furthermore, the present embodiments provide one or more of the following advantages. The metal conductors for write word-line and read word-line in the higher metal layers may have a wider width to provide a lower circuit resistance, which improves the performance of the SRAM cells, such as RC delay. In addition, write ports and read ports of the SRAM cells are separated by continuous gate end dielectric structures, such that source/drain feature bridge concern is prevented.

Thus, one of the embodiments of the present disclosure describes a semiconductor device that includes a first static random access memory (SRAM) cell, a second SRAM cell, a first gate end dielectric structure, and a second gate end dielectric structure. The first SRAM cell includes a first write port including a first write-port pass-gate (WPG) transistor, a second WPG transistor, a first write-port pull-down (WPD) transistor, and a second WPD transistor arranged in a Y-direction, and a first read port including a first read-port pull-down (RPD) transistor and a first read-port pass-gate (RPG) transistor. The second SRAM cell includes a second write-port including a third WPG transistor, a fourth WPG transistor, a third WPD transistor, and a fourth WPD transistor arranged in the Y-direction, and a second read port including a second RPD transistor and a second RPG transistor. The first RPD transistor, the first RPG transistor, the second RPD transistor, and the second RPG transistor are arranged in the Y-direction. The first gate end dielectric structure extends in the Y-direction and is between the first write-port and the first read-port in an X-direction. The second gate end dielectric structure extends in the Y-direction and is between the second write-port and the second read-port in the X-direction.

In another of the embodiments, discussed is a semiconductor device including a first static random access memory (SRAM) cell, a second SRAM cell, a first gate end dielectric structure, a second gate end dielectric structure, a first rectangular via, and a second rectangular via. The first SRAM cell includes a first write-port pull-up (WPU) transistor and a second WPU transistor sharing a first active area extending in a Y-direction, a first write-port pass-gate (WPG) transistor, a second WPG transistor, a first write-port pull-down (WPD) transistor, and a second WPD transistor sharing a second active area extending in the Y-direction, and a first read-port pull-down (RPD) transistor and a first read-port pass-gate (RPG) transistor sharing a third active area extending in the Y-direction. The second SRAM cell includes a third WPU transistor and a fourth WPU transistor sharing a fourth active area extending in the Y-direction, a third WPG transistor, a fourth WPG transistor, a third WPD transistor, and a fourth WPD transistor sharing a fifth active area extending in the Y-direction, and a second RPD transistor and a second RPG transistor sharing the third active area. The first gate end dielectric structure extends in the Y-direction and is between the second active area and the third active area in an X-direction. The second gate end dielectric structure extends in the Y-direction and is between the fifth active area and the third active area in the X-direction. The first rectangular via extends in the X-direction and is electrically connected to gate electrode layers of the first WPD transistor and the first RPD transistor. The second rectangular via extends in the X-direction and is electrically connected to gate electrode layers of the fourth WPD transistor and the second RPD transistor.

In yet another of the embodiments, discussed is a semiconductor device that includes a first static random access memory (SRAM) cell, a second SRAM cell, a first gate end dielectric structure, a second gate end dielectric structure, a first metal layer, and a second metal layer. The first SRAM cell includes a first write port pass-gate (WPG) transistor, a second WPG transistor, a first write-port pull-down (WPD) transistor, and a second WPD transistor sharing a first active area extending in a Y-direction, and a first read-port pull-down (RPD) transistor and a first read-port pass-gate (RPG) transistor sharing a second active area extending in the Y-direction. The second SRAM cell includes a third WPG transistor, a fourth WPG transistor, a third WPD transistor, and a fourth WPD transistor sharing a third active area extending in the Y-direction, and a second RPD transistor and a second RPG transistor sharing the second active area extending in the Y-direction. The first gate end dielectric structure extends in the Y-direction and is between the first active area and the second active area in an X-direction. The second gate end dielectric structure extends in the Y-direction and is between the third active area and the second active area in the X-direction. The first metal layer is over the first SRAM cell and the second SRAM cell. The first metal layer includes a read bit-line conductor extending in the Y-direction and shared by the first SRAM cell and the second SRAM cell. The second metal layer is over the first metal layer. The second metal layer includes a write bit-line conductor and a write bit-line-bar conductor extending in the Y-direction and shared by the first SRAM cell and the second SRAM cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first static random access memory (SRAM) cell, comprising:
a first write port, comprising:
a first write-port pass-gate (WPG) transistor, a second WPG transistor, a first write-port pull-down (WPD) transistor, and a second WPD transistor arranged in a Y-direction; and
a first read port, comprising:
a first read-port pull-down (RPD) transistor and a first read-port pass-gate (RPG) transistor;
a second SRAM cell, comprising:
a second write port, comprising:
a third WPG transistor, a fourth WPG transistor, a third WPD transistor, and a fourth WPD transistor arranged in the Y-direction; and
a second read port, comprising:
a second RPD transistor and a second RPG transistor, wherein the first RPD transistor, the first RPG transistor, the second RPD transistor, and the second RPG transistor are arranged in the Y-direction;
a first gate end dielectric structure extending in the Y-direction and between the first write port and the first read port in an X-direction; and
a second gate end dielectric structure extending in the Y-direction and between the second write port and the second read port in the X-direction.

2. The semiconductor device of claim 1, further comprising:
a first metal layer over the first SRAM cell and the second SRAM cell, wherein the first metal layer comprises a read bit-line conductor extending in the Y-direction, wherein the read bit-line conductor is electrically connected to a source/drain feature of the first RPG transistor and a source/drain feature of the second RPG transistor.

3. The semiconductor device of claim 2, further comprising:
a first via over and electrically connected to a gate structure of the first WPD transistor;
a second via over and electrically connected to a gate structure of the first RPD transistor;
a third via over and electrically connected to a gate structure of the fourth WPD transistor;
a fourth via over and electrically connected to a gate structure of the second RPD transistor; and
a second metal layer over the first metal layer, wherein the second metal layer comprises a first metal conductor and a second metal conductor extending in the X-direction,
wherein the first metal conductor is electrically connected to the first via and the second via, and the second metal conductor is electrically connected to the third via and the fourth via.

4. The semiconductor device of claim 3, further comprising:
a third metal layer over the second metal layer, wherein the third metal layer comprises a write bit-line conductor and a write bit-line-bar conductor extending in the Y-direction,
wherein the write bit-line conductor is electrically connected to source/drain features of the first WPG transistor and the third WPG transistor,
wherein the write bit-line-bar conductor is electrically connected to source/drain features of the second WPG transistor and the fourth WPG transistor.

5. The semiconductor device of claim 4, further comprising:
a fourth metal layer over the third metal layer, wherein the fourth metal layer comprises a first write word-line conductor and a second write word-line conductor extending in the X-direction,
wherein the first write word-line conductor is electrically connected to gate structures of the first WPG transistor and the second WPG transistor,
wherein the second write word-line conductor is electrically connected to gate structures of the third WPG transistor and the fourth WPG transistor.

6. The semiconductor device of claim 1, wherein bottom surfaces of the first gate end dielectric structure and the second gate end dielectric structure are lower than bottom surfaces of gate structures of the first WPG transistor, the second WPG transistor, the first WPD transistor, the second WPD transistor, the first RPD transistor, the first RPG transistor, the third WPG transistor, the fourth WPG transistor, the third WPD transistor, the fourth WPD transistor, the second RPD transistor, and the second RPG transistor.

7. The semiconductor device of claim 1, wherein the first SRAM cell and the second SRAM cell respectively have a first L-shaped cell boundary and a second L-shaped cell boundary in a top view,
wherein the first L-shaped cell boundary abuts the second L-shaped cell boundary to form a rectangular shape.

8. The semiconductor device of claim 7, further comprising:
a third gate end dielectric structure extending in the Y-direction and lengthwise overlapping the first L-shaped cell boundary; and
a fourth gate end dielectric structure extending in the Y-direction and lengthwise overlapping the second L-shaped cell boundary.

9. The semiconductor device of claim 8, further comprising:
first dielectric gate structures extending in the X-direction and in contact with the third gate end dielectric structure; and
second dielectric gate structures extending in the X-direction and in contact with the fourth gate end dielectric structure.

10. The semiconductor device of claim 9, wherein bottom surfaces of the first dielectric gate structures and the second dielectric gate structures are lower than the bottom surfaces of the third gate end dielectric structure and the fourth gate end dielectric structure.

11. A semiconductor device, comprising:
a first memory cell, comprising:
a first transistor and a second transistor sharing a first active area extending in a Y-direction;
a third transistor, a fourth transistor, a fifth transistor, and a sixth transistor sharing a second active area extending in the Y-direction; and
a seventh transistor and a eighth transistor sharing a third active area extending in the Y-direction;
a second memory cell, comprising:
a ninth transistor and a tenth transistor sharing a fourth active area extending in the Y-direction;
a eleventh transistor, a twelfth transistor, a thirteenth transistor, and a fourteenth transistor sharing a fifth active area extending in the Y-direction; and
a fifteenth transistor and a sixteenth transistor sharing the third active area;
a first gate end dielectric structure extending in the Y-direction and between the second active area and the third active area in an X-direction;
a second gate end dielectric structure extending in the Y-direction and between the fifth active area and the third active area in the X-direction;
a first rectangular via extending in the X-direction and electrically connected to gate electrode layers of the fifth transistor and the seventh transistor; and
a second rectangular via extending in the X-direction and electrically connected to gate electrode layers of the fourteenth transistor and the fifteenth transistor.

12. The semiconductor device of claim 11, further comprising:
a first metal layer over the first memory cell and the second memory cell, wherein the first metal layer comprises a read bit-line conductor extending in the Y-direction and electrically connected to a source/drain feature of the eighth transistor and a source/drain feature of the sixteenth transistor.

13. The semiconductor device of claim 12, further comprising:
a second metal layer over the first metal layer, wherein the second metal layer comprises a first write word-line conductor and a second write word-line conductor extending in the X-direction,
wherein the first write word-line conductor is electrically connected to gate structures of the third transistor and the fourth transistor,
wherein the second write word-line conductor is electrically connected to gate structures of the eleventh transistor and the twelfth transistor.

14. The semiconductor device of claim 13, further comprising:
a third metal layer over the second metal layer, wherein the third metal layer comprises a write bit-line conductor and a write bit-line-bar conductor extending in the Y-direction,
wherein the write bit-line conductor is electrically connected to source/drain features of the third transistor and the eleventh transistor,
wherein the write bit-line-bar conductor is electrically connected to source/drain features of the fourth transistor and the twelfth transistor.

15. The semiconductor device of claim 11, further comprising:
a first dielectric gate structure extending in the X-direction and arranged with the first transistor and the second transistor in the Y-direction; and
a second dielectric gate structure extending in the X-direction and arranged with the ninth transistor and the tenth transistor in the Y-direction.

16. The semiconductor device of claim 15, further comprising:
third gate end dielectric structures extending in the Y-direction and separating the first dielectric gate structure from gate structures of the third transistor and the fourth transistor in the X-direction; and
fourth gate end dielectric structures extending in the Y-direction and separating the second dielectric gate structure from gate structures of the eleventh transistor and the twelfth transistor in the X-direction.

17. A semiconductor device, comprising:
a first static random access memory (SRAM) cell, comprising:
a first write-port pass-gate (WPG) transistor, a second WPG transistor, a first write-port pull-down (WPD) transistor, and a second WPD transistor sharing a first active area extending in a Y-direction; and
a first read-port pull-down (RPD) transistor and a first read-port pass-gate (RPG) transistor sharing a second active area extending in the Y-direction;
a second SRAM cell, comprising:
a third WPG transistor, a fourth WPG transistor, a third WPD transistor, and a fourth WPD transistor sharing a third active area extending in the Y-direction; and
a second RPD transistor and a second RPG transistor sharing the second active area extending in the Y-direction;
a first gate end dielectric structure extending in the Y-direction and between the first active area and the second active area in an X-direction;
a second gate end dielectric structure extending in the Y-direction and between the third active area and the second active area in the X-direction;
a first metal layer over the first SRAM cell and the second SRAM cell, wherein the first metal layer comprises a read bit-line conductor extending in the Y-direction and shared by the first SRAM cell and the second SRAM cell; and
a second metal layer over the first metal layer, wherein the second metal layer comprises a write bit-line conductor and a write bit-line-bar conductor extending in the Y-direction and shared by the first SRAM cell and the second SRAM cell.

18. The semiconductor device of claim 17, further comprising:
a source/drain contact over and in contact with the first gate end dielectric structure and the second gate end dielectric structure, wherein the source/drain contact is electrically connected to a source/drain feature shared by the first RPD transistor and second RPD transistor, a source/drain feature shared by the WPD transistor and the second WPD transistor, and a source/drain feature shared by the third WPD transistor and the fourth WPD transistor.

19. The semiconductor device of claim 18, wherein a bottom surface of the source/drain contact is lower than topmost surfaces of the first gate end dielectric structure and the second gate end dielectric structure.

20. The semiconductor device of claim 19, wherein a distance between the bottom surface of the source/drain contact and the topmost surfaces of the first gate end dielectric structure and the second gate end dielectric structure is in a range from about 3 nm to about 50 nm.
